(19) United States
(12) Patent Application Publication
(10) Pub. No.: US 2025/0336048 A1
(43) Pub. Date: Oct. 30, 2025

(54) SYSTEM AND METHOD FOR ROBUST INFERENCE OF HETEROGENEOUS MATERIAL PROPERTIES VIA INFINITE-DIMENSIONAL INTEGRATED DIGITAL IMAGE CORRELATION

(71) Applicant: BOARD OF REGENTS, THE UNIVERSITY OF TEXAS SYSTEM, Austin, TX (US)

(72) Inventors: Omar Ghattas, Austin, TX (US); Joseph Kirchhoff, Austin, TX (US); Thomas O’Leary Roseberry, Austin, TX (US); Dingcheng Luo, Austin, TX (US)

(21) Appl. No.: 19/192,206

(22) Filed: Apr. 28, 2025

Related U.S. Application Data
(60) Provisional application No. 63/639,687, filed on Apr. 28, 2024.

(51) Int. Cl. G06T 7/00

(52) U.S. Cl. CPC G06T 7/0002; G06T 7/97; G06T 2207/20084

(57) ABSTRACT

An exemplary system and method that employ inverse-problem analysis that can determine spatially-varying mechanical parameters in a spatially-varying field of a heterogeneous material. Mathematically, the computation simultaneously poses the inversion program and an image registration problem in a continuum limit function space setting to derive a discretization dimension-independent algorithm for the robust inference of heterogeneous material properties. The algorithm can operate using two or more images of a speckled pattern or other non-uniform patterns applied to, or observable of, the surface of the material in a first state and a second state different from the first state. The difference can be used to assess, via a Newtonian-based operator, the infinite-dimensional spatial fields as state variables that are regularized via a regularization model to constrain the inherent ill-posed nature of inverse problems.

### RELATED APPLICATION

This U.S. application claims priority to, and the benefit of, U.S. Provisional Patent Application No. 63/639,687, filed Apr. 28, 2024, entitled “SYSTEM AND METHOD FOR ROBUST INFERENCE OF HETEROGENEOUS MATERIAL PROPERTIES VIA INFINITE-DIMENSIONAL INTEGRATED DIGITAL IMAGE CORRELATION,” which is incorporated by reference herein in its entirety.

### GOVERNMENT SUPPORT CLAUSE

This invention was made with government support under Grant no. DE-SC0023171 awarded by the Department of Energy and Grant no. 80NSSC22K1203 awarded by the National Aeronautics and Space Administration (NASA). The government has certain rights in the invention.

### BACKGROUND

Engineered materials are often heterogeneous, having grain boundaries, voids, defects, and impurities (intentional or otherwise). Defects in materials can lead to catastrophic failure of complex systems and are often difficult to detect. Examples of engineered materials include carbon fiber composite metal alloys (e.g., steel, platinum alloys, nickel alloys, brash alloys, etc.). Mechanical testing of materials can measure mechanical and material properties (e.g., Young modulus, Poisson's ratio, ductility, yield strength, toughness, fatigue, creep, tensile strength, specific modulus, specific strength, shear modulus, shear strength, resilience, plasticity, hardness, fracture toughness, flexural strength, fatigue limit, among others) in one or two directions using coupons of very specific geometry; they often require a great deal of time to setup to ensure the applied forces are properly loaded and may require equally a great deal of time to run. Common types of mechanical tests include tensile testing, impact testing, creep and fatigue testing, and hardness testing, often using strain gauges or linear variable displacement transducers to destructively pull or push a bulk sample in a static or dynamic manner (e.g., with defined frequencies).

Understanding the behavior of materials with a heterogeneous structure at the micromechanical level can help to predict complex physical processes such as delamination, cracks, and plasticity, among others noted above. Finite element analysis and non-destructive analysis, such as digital image correlation (DIC), have been explored to provide non-destructive evaluation of mechanical and material testing. However, identifying these mechanical and material properties can be challenging due to (i) the nature of the material having more micro and micro components and there being large micro-macro length scale differences among them, (ii) the need for high-resolution analysis, and (iii) modeling complexities such as ambiguities in boundary conditions in the modeling, among others. The Digital Image Correlation (DIC) and other DIC-based full-field deterministic approaches have been proposed for parameter identification. While techniques such as DIC are widely used, such approaches often suffer from high sensitivity to boundary data errors and are limited to the identification of parameters within only well-posed problems, limiting the use of such approaches for non-destructive analysis to very specific material failure conditions. Analyses are often complex, requiring long durations of time (hours) to run.

There is a need and benefit to improving the breadth, reliability, and speed of the non-destructive evaluation of engineered mechanical/material systems using advanced algorithms to complement mechanical testing with the need for conventional mechanical or material testing.

### SUMMARY

An exemplary non-destructive image registration and inverse problem analysis system and method are disclosed that employ (i) an inverse problem solver that solves a mathematical optimization problem that determines material properties that minimize the error between the corresponding prediction (e.g., displacement prediction or the like) of the physical model and the observed data (e.g., displacement field data) and (ii) simulation of the physics of solid mechanics in a finite element analysis or a surrogate model (e.g., AI/ML) of the same that can determine spatially-varying mechanical parameters (such as linear elasticity and hyper-elasticity, among others described herein) in a spatially-varying field of a heterogeneous material (e.g., engineered material). Notably, the inverse problem analysis system can determine the spatially varying mechanical/material parameters of a sample at both small and large scales that can detect inclusions and other material defects. To do so, the inverse problem analysis system is configured to analyze complex high-dimensional heterogeneous material properties as a material defect detection problem in its high-dimensional representation via the use of adjoint methods to efficiently compute gradients. In some embodiments, the adjoint model may be performed with Hessian actions associated with the joint optimization IDIC problem, leading to state-of-the-art inverse problem solutions via Newton methods or other gradient-based operators. The exemplary non-destructive image registration and inverse problem analysis system and method can solve complex, large-scale material defect detection problems efficiently and provide solutions of interest to modern engineering tasks. Adjoint-based gradients and Hessian actions, as employed the exemplary system and method and worked out at the infinite-dimensional level, can avoid differentiating through numerical artifacts. Prior IDICs do not solve the nonlinear combined inverse problem and instead do a linearization and discretizes before minimization operation, the optimization of which often handles discontinuities, such as a hole or void, poorly.

Mathematically, the exemplary computation simultaneously poses the inversion problem and an image registration problem in a continuum limit function space setting (e.g., infinite dimensionality) to derive a discretization dimension-independent algorithm for the robust inference of heterogeneous material properties such as stress field, Lame parameters, modulus field, strain field, linear elasticity values, hyperelasticity values, fracture mechanic values, plasticity values, or a combination thereof, among others, while maintaining sharpness of features in their reconstruction. The exemplary algorithm can operate using two or more images of a speckled pattern or other non-uniform patterns (e.g., having spatial features) applied to, or observable of, the surface of the material in a first state (e.g., a baseline state) and a second state different from the first state (e.g., a comparison state in which a force different from the first state is applied to the sample). The difference can be used to assess, via a Newtonian-based operator or other gradient-based operators, the infinite-dimensional spatial fields as state variables that are regularized via a regularization model to constrain the inherent ill-posed nature of inverse problems. The algorithm is thus termed “Infinite-Dimensional integrated digital image correlation” or “∞-dim IDIC.” Indeed, the exemplary ∞-dim IDIC evaluation can be performed using inputs of two or more images of sample and measurement or estimation of an induced displacement of the sample.

In some embodiments, the exemplary inverse problem (referred to as the ∞-dim IDIC inverse problem) is solved in a unified operation that both (i) solve a mathematical optimization problem that determines material properties that minimize the error between the corresponding prediction (e.g., displacement prediction) of the physical model and the observed data (e.g., displacement field data) and (ii) analyzes the physics of solid mechanics simulated in a finite element analysis or a surrogate model (e.g., AI.ML) of the same, in one simultaneous optimization problem whereby the displacements are constrained to obey the same physics as the corresponding inverse problem (and, e.g., not computed with statistical (e.g., cross-correlation) algorithms and the like).

In another embodiment, the exemplary inverse problem (referred to as a “two-way ∞-DIC” or “∞-dim DIC-based” approach herein) is solved as a supplemental analysis step following digital image correlation (DIC) analysis, which separately and initially determines a displacement map from two images to later provide the determined displacement map to the exemplary inverse problem. The two-way ∞-dim DIC operation can leverage popular DIC operations to provide a distinct operation from conventional DIC that provides a quicker and more accurate estimation of material/mechanical properties and/or defects than conventional DIC. The unified ∞-dim IDIC can be performed more quickly and more accurately than its two-way counterpart, which provides an initial displacement map rather an iterating it during the optimization problem solving. From testing, it was observed that the unified ∞-dim IDIC can be performed in minutes. The two-way ∞-dim DIC operation can be performed in comparable runtime but would require additional time to run the DIC analysis. The use of surrogate (AI/ML) models as a substitute for FEA analysis can allow the unified ∞-dim IDIC to operate in real-time or near real-time.

For either ∞-dim IDIC or ∞-dim DIC-based operation, for the image registration, the sample to be analyzed may be a test coupon mounted in a mechanical test or may be a live part being subjected to mechanical testing or in-situ non-destructive evaluation. So long as an induced displacement measurement having (i) the applied force or condition and (ii) a measure of the displacement or images can be acquired, the exemplary system and method can be performed. Notably, the exemplary system and method provide a paradigm shift in material characterization and mechanical testing and evaluation in allowing for the evaluation of complex high-dimensional heterogenous material properties, the speed of the analysis, and the accuracy. The exemplary system and method can be employed for the spatially-varying mechanical propert(ies) evaluation of a sample such as engineering materials, biological tissues, composite materials, welds, and foams, among others, as a full-field measurement to identify spatially varying properties of such samples.

Also, notably, the discretization dimension-independent algorithm is both scalable and efficient. The exemplary algorithm was evaluated and determined to be mesh-independent, a metric indicating a strong algorithm that is not dependent on specific meshing topology. The algorithm may be used in an offline analysis or in real-time applications.

The exemplary system and method can be used for (i) finite element model (FEM) validation, (ii) nondestructive or destructive evaluation of structures, or (iii) non-intrusive early prediction of damage, e.g., for certification or early damage detection, e.g., for aerospace and civil industries, among others. Speckled patterns provide features that overcome the inherent noisy and uncertain displacement in the sample to which parameter identification can be captured. The exemplary system and method can operate on samples with no priori knowledge of the constitutive model.

In addition to non-destructive evaluation, the exemplary system and method may be implemented across disciplines, e.g., mechanics (Digital Image Correlation, DIC), fluids (Particle Tracking Velocimetry), rheometry (Micro-Rheometry), medical (Image Registration or Elastography), robotics (Point-Set Registration), and most broadly known as Optical Flow. In some embodiments, the fields merge, as is the case of tracking the oil spill of Deep Horizon or in biomechanics. The framework may be formulated for specific disciplines. For example, Optical Flow usually invokes a transport model, whereas classical DIC typically uses a kinematics approach. The joint/integrated inversion analysis can be applied to any of these fields. The optimization problem of the flow of feature sets between the initial and deformed state can be generalized, e.g., the spatial field can be used to invert for parameters of interest such as elastic moduli, viscosity, tumor growth, etc.

In an aspect, a method is disclosed comprising: receiving input data comprising (i) at least two images (2D or 3D) of a feature pattern (e.g., speckled pattern) formed over a sample (e.g., comprising heterogeneous material having one or more compositions or one or more solid phases), including a first measured image and a second measured image, and (ii) a measurement or estimation of an induced displacement of the sample, wherein the first measured image was acquired at a first state of the sample, and wherein the second measured image was acquired at a second state different from the first state due to the induced displacement (e.g., mechanical work, thermal work, electromagnetic work or any work capable of inducing displacement) of the sample when at least one of the image was captured; performing an inverse problem analysis (having inverse problem solver+physic-based model+DIC (if applicable)) configured to determine a material field data comprising a plurality of spatially varying mechanical or material parameters in a spatially varying field of the sample using (i) the at least two images or a displacement map (e.g., from DIC analysis) derived from the same and (ii) the measurement or estimation of the induced displacement of the sample, wherein the determined material field data is provided as input to a physics-based model (e.g., finite element analysis or a surrogate model trained to do the same) to generate a model-derived displacement estimate from the material field data (e.g., (i) using error determined between pixels, e.g., for inf-dim IDIC or (ii) error between predicted displacement field, e.g., for inf-dim DIC-based analysis), wherein the plurality of spatially varying mechanical parameters are determined for a plurality of spatially defined locations in the sample; and outputting, via a graphical user interface or report, the plurality of spatially varying mechanical or material parameters in the spatially-varying field of the sample or a defect estimation derived therefrom, wherein the spatially varying mechanical or material parameter in the spatially-varying field of the sample or the defect estimation derived therefrom is subsequently employed in material characterization, defect estimation, and/or mechanical testing and evaluation of the sample (e.g., to evaluate structures for certification or early damage detection).

In some embodiments, the inverse problem analysis further includes, prior to determining the material field data, determining, via DIC analysis, a displacement field data (e.g., difference/flow/transition/correlation) between the first measured image and the second measured image, wherein the displacement field data is used as an input to inverse problem analysis, and wherein the inverse problem analysis is configured to determine the material field data based on predicted displacement field.

In some embodiments, the inverse problem analysis comprises a Newtonian-based operator configured to assess the displacement field data in an infinite-dimensional spatial field (e.g., as state variables that are regularized via a regularization model (e.g., L²(Ω) Tikhonov regularization, H¹(Ω) Tikhonov smoothing regularization, and/or primal-dual Total Variation regularization).

In some embodiments, the inverse problem analysis includes a gradient-based operator (e.g., Broyden-Fletcher-Goldfarb-Shanno (BFGS)) configured to assess the displacement field data in an infinite-dimensional spatial field (e.g., as state variables that are regularized via a regularization model using first and second derivatives of a gradient of the at least two images and the induced displacement of the sample).

In some embodiments, the inverse problem analysis (e.g., Newtonian-based operator or gradient-based operator) is configured to compute adjoint-based gradients and/or Hessian actions in a minimization operation.

In some embodiments, at least one of the adjoint-based gradients and/or Hessian actions is employed to infer a probability distribution of the plurality of spatially varying mechanical or material parameters.

In some embodiments, the physics-based model comprises a finite element analysis configured to generate a model-derived displacement estimate from the material field data (the finite element may be down-selected from a set of FEA analyses using AI/ML).

In some embodiments, the physics-based model comprises a trained AI model as a surrogate of finite element analysis, configured to generate a model-derived displacement estimate from the material field data, wherein the physics-based model is selected from the group consisting of a convolutional neural network (CNN), a transformer, a Fourier neural operator, a reduced basis neural operator, or a combination thereof.

In some embodiments, the plurality of spatially varying mechanical or material parameters comprises at least one of a stress field, Lame parameters, modulus field, strain field, linear elasticity values, hyperelasticity values, fracture mechanic values, plasticity values, or a combination thereof, for the plurality of spatial-defined locations in the sample.

In some embodiments, the inverse problem analysis comprises a Newtonian-based operator or a gradient-based operator, either comprising a regularization model comprising an L²(Ω) Tikhonov regularization, an H¹(Ω) Tikhonov smoothing regularization, or primal-dual Total Variation regularization.

In some embodiments, the measured images comprise CCD camera images, infrared camera images, sensor images, profilometer scans, microscopy images (e.g., Scanning, Tunneling, Confocal), x-ray images, or CT scans.

In another aspect, a system is disclosed comprising: a processor; and a memory having instructions stored thereon, wherein execution of the instructions by the processor causes the processor to: receive input data comprising (i) at least two images (2D or 3D) of a feature pattern (e.g., speckled pattern) formed over a sample (e.g., comprising heterogeneous material having one or more compositions or one or more solid phases), including a first measured image and a second measured image, and (ii) a measurement or estimation of an induced displacement of the sample, wherein the first measured image was acquired at a first state of the sample, and wherein the second measured image was acquired at a second state different from the first state due to the induced displacement (e.g., mechanical work, thermal work, electromagnetic work or any work capable of inducing displacement) of the sample when at least one of the image was captured; perform an inverse problem analysis (having inverse problem solver+physic-based model+DIC (if applicable)) configured to determine a material field data comprising a plurality of spatially varying mechanical or material parameters in a spatially varying field of the sample using (i) the at least two images or a displacement map (e.g., from DIC analysis) derived from the same and (ii) the measurement or estimation of the induced displacement of the sample, wherein the determined material field data is provided as input to a physics-based model (e.g., finite element analysis or a surrogate model trained to do the same) to generate a model-derived displacement estimate from the material field data (e.g., (i) using error determined between pixels, e.g., for inf-dim IDIC or (ii) error between predicted displacement field, e.g., for inf-dim DIC-based analysis), wherein the plurality of spatially varying mechanical parameters are determined for a plurality of spatially defined locations in the sample; and output, via a graphical user interface or report, the plurality of spatially varying mechanical or material parameters in the spatially-varying field of the sample or a defect estimation derived therefrom, wherein the spatially varying mechanical or material parameter in the spatially-varying field of the sample or the defect estimation derived therefrom is subsequently employed in material characterization, defect estimation, and/or mechanical testing and evaluation of the sample (e.g., to evaluate structures for certification or early damage detection).

In some embodiments, the inverse problem analysis further comprises, prior to determining the material field data, determining, via DIC analysis, a displacement field data (e.g., difference/flow/transition/correlation) between the first measured image and the second measured image, wherein the displacement field data is used as an input to inverse problem analysis, and wherein the inverse problem analysis is configured to determine the material field data based on predicted displacement field.

In some embodiments, the inverse problem analysis comprises a Newtonian-based operator configured to assess the displacement field data in an infinite-dimensional spatial field (e.g., as state variables that are regularized via a regularization model (e.g., L²(Ω) Tikhonov regularization, H¹(Ω) Tikhonov smoothing regularization, and/or primal-dual Total Variation regularization).

In some embodiments, the inverse problem analysis comprises a gradient-based operator (e.g., Broyden-Fletcher-Goldfarb-Shanno (BFGS)) configured to assess the displacement field data in an infinite-dimensional spatial field (e.g., as state variables that are regularized via a regularization model using first and second derivatives of a gradient of the at least two images and the induced displacement of the sample).

In some embodiments, the inverse problem analysis (e.g., Newtonian-based operator or gradient-based operator) is configured to compute adjoint-based gradients and/or Hessian actions in a minimization operation.

In some embodiments, the physics-based model comprises a finite element analysis configured to generate a model-derived displacement estimate from the material field data (the finite element may be down-selected from a set of FEA analyses using AI/ML).

In some embodiments, the physics-based model comprises a trained AI model as a surrogate of finite element analysis, configured to generate a model-derived displacement estimate from the material field data, wherein the physics-based model is selected from the group consisting of a convolutional neural network (CNN), a transformer, a Fourier neural operator, a reduced basis neural operator, or a combination thereof.

In some embodiments, the system includes a CCD camera, an infrared camera, a sensor, a profilometer, a microscope, an x-ray scanner, or a CT scanner configured to acquire the input data for the inverse problem analysis.

In another aspect, a non-transitory computer-readable medium having instructions stored thereon, wherein execution of the instructions by a processor causes the processor to:
receive input data comprising (i) at least two images (2D or 3D) of a feature pattern (e.g., speckled pattern) formed over a sample (e.g., comprising heterogeneous material having one or more compositions or one or more solid phases), including a first measured image and a second measured image, and (ii) a measurement or estimation of an induced displacement of the sample, wherein the first measured image was acquired at a first state of the sample, and wherein the second measured image was acquired at a second state different from the first state due to the induced displacement (e.g., mechanical work, thermal work, electromagnetic work or any work capable of inducing displacement) of the sample when at least one of the image was captured;
perform an inverse problem analysis (having inverse problem solver+physic-based model+DIC (if applicable)) configured to determine a material field data comprising a plurality of spatially varying mechanical or material parameters in a spatially varying field of the sample using (i) the at least two images or a displacement map (e.g., from DIC analysis) derived from the same and (ii) the measurement or estimation of the induced displacement of the sample, wherein the determined material field data is provided as input to a physics-based model (e.g., finite element analysis or a surrogate model trained to do the same) to generate a model-derived displacement estimate from the material field data (e.g., (i) using error determined between pixels, e.g., for inf-dim IDIC or (ii) error between predicted displacement field, e.g., for inf-dim DIC-based analysis), wherein the plurality of spatially varying mechanical parameters are determined for a plurality of spatially defined locations in the sample; and
output, via a graphical user interface or report, the plurality of spatially varying mechanical or material parameters in the spatially-varying field of the sample or a defect estimation derived therefrom, wherein the spatially varying mechanical or material parameter in the spatially-varying field of the sample or the defect estimation derived therefrom is subsequently employed in material characterization, defect estimation, and/or mechanical testing and evaluation of the sample (e.g., to evaluate structures for certification or early damage detection).

### BRIEF DESCRIPTION OF DRAWINGS

FIGS. 1A-1B each shows an example system that employs computation of an ∞-dim IDIC inverse problem analysis and physics-based physical model (or surrogate model) to determine spatially varying mechanical or material parameters (e.g., linear elasticity, hyper-elasticity, etc.) in a spatially varying field of a heterogeneous material (e.g., engineered material), in accordance with an illustrative embodiment. FIG. 1A shows an ∞-dim IDIC analysis and defect detection system having an ∞-dim IDIC inverse problem solver and a physics-based model (e.g., finite element analysis (FEA) or surrogate model, e.g., artificial intelligence (AI), or machine learning (ML) model) for inverse problem analysis and computation. FIG. 1B shows an ∞-dim DIC-based analysis having a modified version of the ∞-dim DIC-based inverse problem solver that also operates with the physics-based model and has a separate DIC analysis.

FIGS. 2A-2C show example implementation/formulation of the inverse problem solver (e.g., ∞-dim IDIC, ∞-dim DIC-based in the exemplary system of FIGS. 1A and 1B. FIG. 2A shows an ∞-dim IDIC inverse problem solver and its implementation/formulation to determine material field data using at least two images and a measured/predicted induced displacement of the sample/substrate. FIG. 2B shows an ∞-dim DIC-based inverse problem solver and its implementation/formulation to determine a material field data using only a displacement field data (e.g., difference/flow/transition/correlation) between the first measured image and the second measured image determined by a DIC analyzer. FIG. 2C shows an example schematic of an example setup of boundary conditions for either ∞-dim IDIC or ∞-dim DIC-based system.

FIGS. 3A-3C show example runtime operation flow and methods of performing inverse-problem analysis that can determine spatially-varying mechanical parameters (such as linear elasticity and hyperelasticity, among others described herein) in a spatially-varying field for the exemplary system, in accordance with an illustrative embodiment. FIG. 3A shows an example runtime operation flow 300a for the exemplary system of FIGS. 1A and 1B. FIG. 3B shows an example method of performing the ∞-dim IDIC inverse-problem analysis of FIG. 1A. FIG. 3C shows an example method of performing ∞-dim DIC-based inverse-problem of FIG. 1B.

FIGS. 4A-4B each shows an example diagram for the operation flow for the ∞-dim IDIC system.

FIG. 4C shows an example diagram for the operation flow for the ∞-dim DIC-based system.

FIGS. 5A-5Q show implementation and evaluation results for the exemplary ∞-dim IDIC system. FIG. 5A shows a schematic of the synthetic data generation process. FIG. 5B shows a method to perform the synthetic data generation process. FIG. 5C shows example steps of an inverse problem analysis. FIG. 5D shows an example visualization in the post-processing of the displacement field. FIG. 5E shows a selection of example inversions, illustrating the inference of complex material fields for linear elasticity. FIG. 5F presents results for six cases of complex modulus fields, with inference conducted starting from the same initial guess of 2. FIG. 5G demonstrates the mesh-independent performance of the exemplary method for H¹ regularization on the parameter where the mesh increased from 100×100, 200×200 to 300×300 for a tensile experiment using 5×5 features on a hyperelastic medium with ˜5% strain. FIG. 5H demonstrates the inference for varied meshes using H¹ and TV. FIG. 5I demonstrates the mesh-independent performance for varying mesh sizes for the Hyperelasticity problem using the primal-dual TV formulation. FIG. 5J illustrates the outcomes for three distinct scenarios: a void inclusion, a bump function, and a Gaussian random field. FIG. 5K shows a resulting image pattern with image brightness noise added to the deformed image. FIG. 5L shows the effect of noise on the accuracy opf the inferred results for Hyperelasticity. FIG. 5M shows the relationship between the size of features in the material, which is dependent on the speckle size. FIG. 5N shows an investigation of a 3×3 feature size on a 100×100 mesh while varying the speckle size from 0.25 to 0.000244, with the number of features held constant. FIG. 5O shows additional deformation, caused by increased normal force on the synthetic image, improving the inference of the physics-based model. FIGS. 5P-5Q shows inference solutions for compression, tension, and bending.

FIGS. 6A-6I show implementation and evaluation results for the exemplary ∞-dim DIC-based system. FIG. 6A shows an example three-point bending setup with a displacement field known a priori. FIGS. 6B-6C show the noisy displacement field (experimental data) and the noise, respectively. FIG. 6D shows the inverse result using total variation (i.e., piecewise constant regularization), wherein the scale bar is logarithmic. FIG. 6E shows an inversion result using rudimentary Tikhonov regularization (L2 minimization with respect to a nominal value, taken to be zero). FIG. 6F shows example displacement field data measured by a DIC analysis. FIG. 6G shows the inversion for one of the samples. FIGS. 6H-6I shows the behaviors of the two polymers (e.g., white/gray lossy polymer, red stiff polymer) under a tensile experiment.

### DETAILED DESCRIPTION

To facilitate an understanding of the principles and features of various embodiments of the present invention, they are explained hereinafter with reference to their implementation in illustrative embodiments.

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the n-th reference in the list. All references cited and discussed in this specification are incorporated herein by reference in their entirety and to the same extent as if each reference was individually incorporated by reference.

∞-dimension IDIC Operator. Digital Image Correlation (DIC) is a type of image registration to measure changes between two images, e.g., to infer displacement, e.g, in engineering material analysis. By tracking features (usually speckle patterns), DIC algorithms can perform the image registration by measuring changes in the two images using cross-correlation. Since the 1980s, the technology has been extensively used in laboratory settings to learn about heterogeneous deformation fields as well as for validating finite element codes. Herein, the displacement field solution, e.g., from DIC has been extended to determine material properties that are consistent with the displacement field data (i.e., by solving an inverse problem). The exemplary ∞-dim IDIC inverse problem is solved as a mathematical optimization problem where one determines material properties that minimize the error between the corresponding displacement prediction of the physical model and the observed displacement field data. The physics of solid mechanics are typically simulated via the finite element analysis method or a surrogate model thereof. This process, referred to as parameter identification, is done separately from the image registration.

Herein, an ∞-dim IDIC operation integrates the image registration and subsequent inverse problem in a unified framework as a single simultaneous optimization problem whereby the displacements are not computed with statistical (e.g., cross-correlation) algorithms but are themselves constrained to obey the same physics as the corresponding inverse problem.

The exemplary ∞-dim IDIC system and method notably can be applied to complex high-dimensional heterogeneous material properties, distinct from low-dimensional problems such as learning in a lab setting, which facilitates its (exemplary ∞-dim IDIC) use in complex, large-scale material defect detection problems, which are of interest to modern engineering tasks. The exemplary ∞-dim IDIC system and method can operate with infinite dimensions, e.g., within a Bayesian inference setting to account for uncertainty.

Dimension-independent-IDIC. The exemplary system and method employ an ∞-dim IDIC-like algorithm (or ∞-dimDIC-based) for high-dimensional material property estimation problems that allow for the inference of spatial variations in material properties at small scales, enhancing the ability to detect inclusions and other material defects. The exemplary system and method can solve the material defect detection problem in its high-dimensional representation via, e.g., the use of adjoint methods to efficiently compute gradients and Hessian actions associated with the joint optimization IDIC problem, leading to state-of-the-art inverse problem solutions via Newton methods. The algorithm can be referred to as being a dimension-independent IDIC formulation, as the convergence properties of the methods are independent of the discretization dimension of the finite element method used to simulate the physics. In contrast, prior IDIC methods do not solve a nonlinear combined inverse problem as described herein and instead perform a linearization and discretization before minimization operation, the optimization of which has been observed to handle discontinuities (e.g., of holes or voids) poorly.

Dimension-independent Bayesian IDIC. In addition, to properly quantify uncertainties in material defect detection, which are essential to quantifying risk in engineering settings, the exemplary system and method can additionally pose the dimension-independent IDIC problem as a Bayesian statistical inference problem. Using the formulation, the algorithm can employ sophisticated gradient and Hessian-based Bayesian algorithms to infer a probability distribution of material defects that is consistent with the imperfect observations of the displacements instead of merely a single estimate. The formulation can be referred to as dimension-independent Bayesian IDIC.

Bayesian model selection using dimension-independent IDIC. In solid mechanics, the mathematical representation (models) of the material behavior is not generally known and may vary substantially from one material to another (e.g., aluminum versus composites). These models are referred to as constitutive models. In situations where different constitutive models may be applied to the same material, the choice of constitutive model can introduce additional uncertainty. The exemplary system and method may employ a dictionary of known models which can each independently be used to solve dimension-independent Bayesian IDIC problems. The Bayesian representations of the inferred material properties can be ranked in how well they describe the observations via the use of the Bayesian model evidence, to, e.g., allow engineers to find a high-quality material defect reconstruction by additionally taking the underlying PDE model into account. The additional operation can be referred to as the Bayesian model selection using dimension-independent IDIC.

The ∞-dim IDIC analysis (and ∞-dim DIC-based analysis) can employ a dimension-independent IDIC problem formulated as a Bayesian inference problem. With the formulation, the ∞-dim IDIC analysis can employ sophisticated gradient (e.g., adjoint state method) and Hessian-based Bayesian algorithms to infer a probability distribution of material defects that are consistent with our imperfect observations of the displacements. Dimension-independent refers to the formulation benefically, not scaling with the problem dimension.

Furthermore, uncertainty can be incorporated into digital twin models downstream. Bayesian model selection naturally “learns” which constitutive model describes the observations, enabling engineers to work on problems where the model isn't intuitively known.

AI/ML Surrogates of ∞-dim IDIC. To reduce computational costs of the dimension-independent IDIC and its Bayesian formulations, which may be intractable due to the computational costs of the PDE simulations via the finite-element method, neural operator surrogates, e.g., machine learning and AI, may be used to learn the mathematical relationship between the material properties and the resulting displacement fields. A derivative-informed neural operator can be employed to dramatically reduce the computing times of the forward solves (and derivative information for the optimization scheme). The trained AI model (e.g., neural operator can be trained using the output of the finite element method as the ground truth and modulus fields and traction conditions as the input.

The learned representations via a trained AI/ML model can be orders of magnitude faster than the corresponding PDE simulation via the finite element method. The trained AI/ML model can also make use of dimension-independent information similar to the dimension-independent IDIC method, leading to efficient learning formulations and representations for large-scale PDE problems. With certain AI/ML operations, the ∞-dim IDIC prediction may be performed near-real-time performance via AI/MHL hardware acceleration.

### Example System

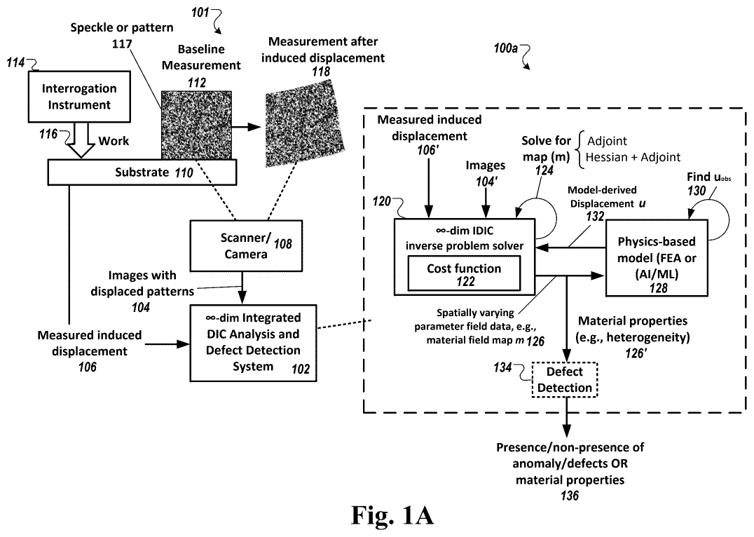

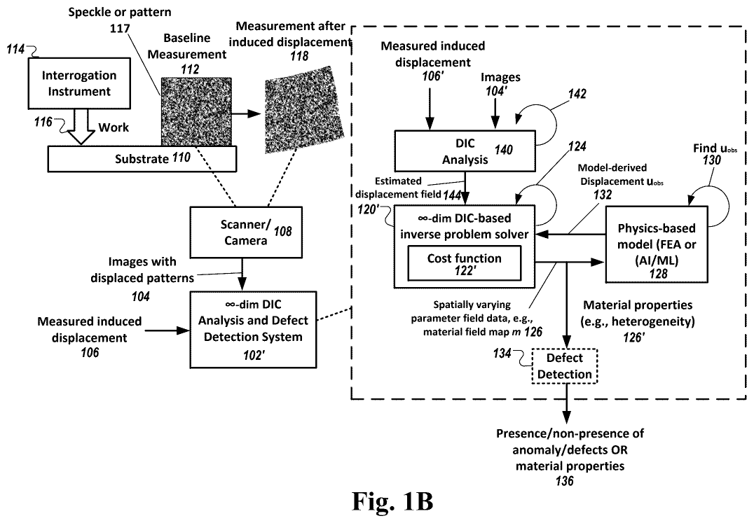

FIGS. 1A-1B each shows an example system 100 (shown as 100a, 100b) that employs computation for inverse problem analysis configured to determine spatially varying mechanical or material parameters (e.g., linear elasticity, hyper-elasticity, etc.) in a spatially varying field of a heterogeneous material (e.g., engineered material), in accordance with an illustrative embodiment. FIG. 1A employs an ∞-dim IDIC analysis and defect detection system 102 having an ∞-dim IDIC inverse problem solver 120 and a physics-based model 128 (e.g., finite element analysis (FEA), artificial intelligence (AI), or machine learning (ML) model) for inverse problem analysis and computation. FIG. 1B employs an ∞-dim DIC-based analysis and defect detection system 102 and the same physics-based model 128 for inverse problem analysis and computation.

Integrated DIC Analysis and Defect Detection System. In the example shown in FIG. 1A, the ∞-dim IDIC inverse problem solver 120 (of the ∞-dim IDIC analysis and defect detection system 102) is configured, during run-time operation, to receive image data 104 (shown as 104′) (e.g., from a data store) having at least two images 112, 118 with displaced patterns 117 acquired from a test cell 101 comprising a camera or scanner 108 of a substrate 110 (i.e., sample) of interest having a speckled or pattern 117 formed thereon. The test cell 101 can include an interrogation instrument 114 (or environment chamber) configured to apply a work 116 on the substrate 110 as a sample of interest to induce a displacement of the substrate 110, to which a second image 118 can be acquired by the scanner/camera 108. The image data 104 may include only the second state image 118, where speckles or patterns of the baseline measurement are reproducible on the substrate 110 and stored as a retrievable baseline image (e.g., as the first image 112). The scanner/camera 108 is preferably a CCD camera but can be, as a non-limiting example, an infrared camera, a sensor, a profilometer, a microscope, an x-ray scanner, or CT scanner configured to acquire the input data for the inverse problem analysis. The two measured images 112 and 118 can comprise CCD camera images, infrared camera images, sensor images, profilometer scan, microscopy images (e.g., Scanning, Tunneling, Confocal), x-ray images, or CT scan.

In some embodiments, 2 images are employed. In other embodiments, 3, 4, 5, 6, 7, 8, 9, 10, 11, 12, 13, 14, 15, 16, 17, 18, 19, 20, 21, 22, 23, 24, 25, 26, 27, 28, 29, 30 images are employed. In some embodiments, more than 30 images are employed.

The induced displacement of the substrate 110 can be between 1% and 20%. Different degrees of induced displacement can provide different mechanical or material properties that can be detected or generated by the systems (e.g., 100a, 100b). However, when the degree of induced displacement reaches a certain threshold, the substrate 110 can either break or the mechanical or material properties of the substrate 110 remain the same until the breaking point.

The ∞-dim IDIC inverse problem solver 120 also receives a measurement or estimation of the induced displacement 106 (shown as 106′) of the substrate 110 that was applied to the substrate 110 when the measurements (112, 118) were acquired. The induced displacement 106 is preferably caused by mechanical work applied to the sample 110 (e.g., applied force, load, shear, compression, tensile, etc.) but can be other work or supplemented with other work, such as and not limited to thermal work, electromagnetic work, or any work capable of inducing displacement that is observable per the speckle or pattern 117 by the scanner/camera 108.

The ∞-dim IDIC inverse problem solver 120 is configured to perform an inverse problem analysis by solving for a spatially varying parameter map 126 (denoted as m), having material field data (e.g., material properties 126′), in a cost function 122 over a plurality of iterations 124 (e.g., corresponding to the sizes of the two measured images 112 and 118). The cost function 122 may depend on the model-derived displacement estimate 132 (e.g., u or u_{obs}) and the spatially varying parameter map 126 (e.g., m) derived from the first and second measured images 112 and 118. In some embodiments, the cost function 122 is based on the minimization of (a) a data misfit function having (i) the first measured image 112 combined with a model-derived displacement field u (e.g., 132) and (ii) the second measured image 118 and (b) a regularization function. The ∞-dim IDIC inverse problem solver 120 can continuously solve for the spatially varying parameter map 126 (e.g., material field map) in the cost function 122 over multiple iterations (in a loop 124) until the spatially varying parameter map 126 converges (i.e., until adjoint-based gradients and/or Hessian action of the spatially varying parameter map 126 satisfy predefined criteria) by applying a Newtonian-based operator or a gradient-based operator (either comprising a regularization model comprising an L²(Ω) Tikhonov regularization, an H¹(Ω) Tikhonov smoothing regularization, or primal-dual Total Variation regularization) to the two measured images 112, 118 and the measurement or estimation of the measured induced displacement 106. The regularization model can be pre-calculated and stored for usage during runtime analysis.

The Newtonian-based operator (in FIG. 1A), or other gradient operator (e.g., Broyden-Fletcher-Goldfarb-Shanno (BFGS)), is configured to assess the displacement field data (e.g., 132 from the physics-based model) in an infinite-dimensional spatial field (e.g., as state variables that are regularized via a regularization model (e.g., L²(Ω) Tikhonov regularization, H¹(Ω) Tikhonov smoothing regularization, and/or primal-dual Total Variation regularization), e.g., using derivatives (e.g., first and second derivatives) of a gradient of the estimated and model-derived displacement fields (e.g., 144, 132) and the induced displacement of the substrate 110).

In each iteration, after solving for the spatially varying parameter field map 126, the ∞-dim IDIC inverse problem solver 120 can provide the spatially varying parameter field map 126, e.g., comprising material field data, as an input to the physics-based model 128 (e.g., a FEA or surrogate model thereof, e.g., AI/ML model). The spatially varying parameter field map 126 can comprise a plurality of spatially varying mechanical or material parameters (shown as “material properties” 126′) in a spatially varying field of the substrate 110 (i.e., sample). The physics-based model 128 may use the measured induced displacement 106 in its analysis, e.g., as a traction condition, t, on the boundary condition of the FEA analysis.

The physics-based model 128 receives the spatially varying parameter field map 126 with material field data from the ∞-dim IDIC inverse problem solver 120; the model 128 then generates a model-derived displacement field estimate 132 using a finite element analysis employing the revised material field data in the FEA analysis. The finite element analysis 128 preferably has a pre-defined or pre-established mesh, boundary, and execution conditions, PDE, etc., that can operate on the revised material field data to determine a revised model-derived displacement field to provide back to the ∞-dim IDIC inverse problem solver 120 for further computation (e.g., 122).

Once the ∞-dim IDIC inverse problem solver 120 and physics-based model 128 converge to a solution, the output of the ∞-dim IDIC inverse problem solver 120 can be directly or indirectly outputted, via a graphical user interface or report, where the material properties 126′ corresponding to the map 126 having the spatially varying mechanical or material parameter in the spatially-varying field of the substrate 110 can be used for material characterization, defect estimation, and/or mechanical testing and evaluation of the substrate 110. Indeed, the mechanical or material parameter 126′ can be provided to a defect estimator 134 for defect estimation. As an example, mechanical and material parameters 126′ may include and are not limited to stress field, Lame parameters, modulus field, strain field, linear elasticity values, hyperelasticity values, fracture mechanic values, plasticity values, or a combination thereof, for a plurality of spatial-defined locations in the substrate 110. The mechanical and material parameters 126′ may alternatively include and are not limited to Young modulus, Poisson's ratio, ductility, yield strength, toughness, fatigue, creep, tensile strength, specific modulus, specific strength, shear modulus, shear strength, resilience, plasticity, hardness, fracture toughness, flexural strength, fatigue limit, among others that may be determined per the FEA model, displacement map, or material map.

The defect estimation, e.g., can be an anomaly detector or a threshold detector that can be used to determine and output an indication 136 of the presence/non-presence of anomaly/defects or material properties to reject/pass the part, a batch of the part, or a process associated with the part. In some embodiments, the output (mechanical or material parameter 126′ or indication 136 of the presence/non-presence of anomaly/defects) can be used to direct further analysis, e.g., destructive evaluation of the sample.

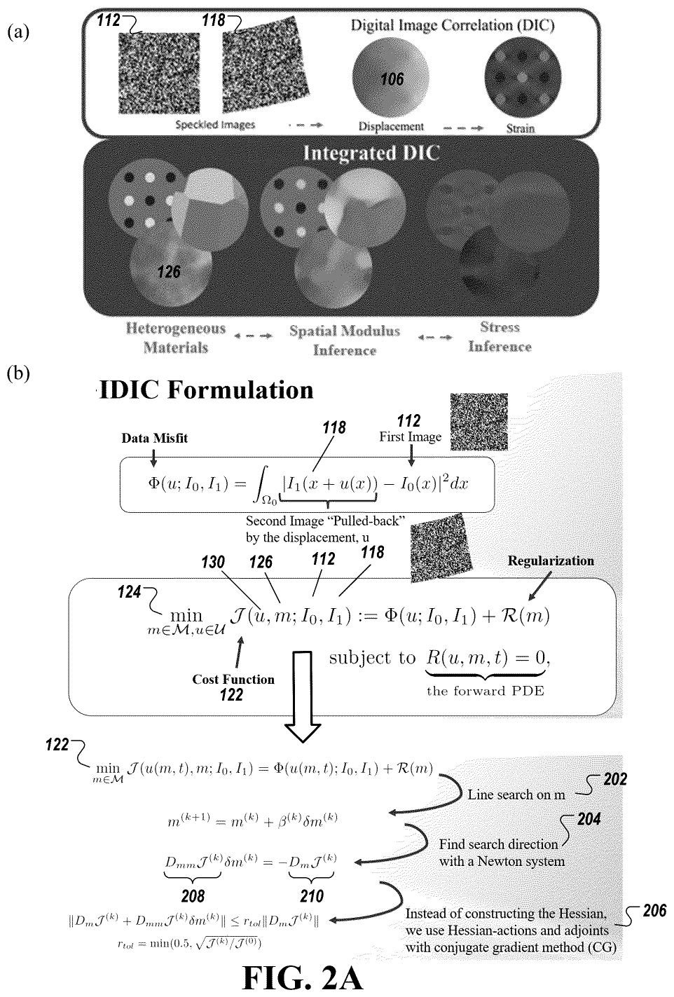

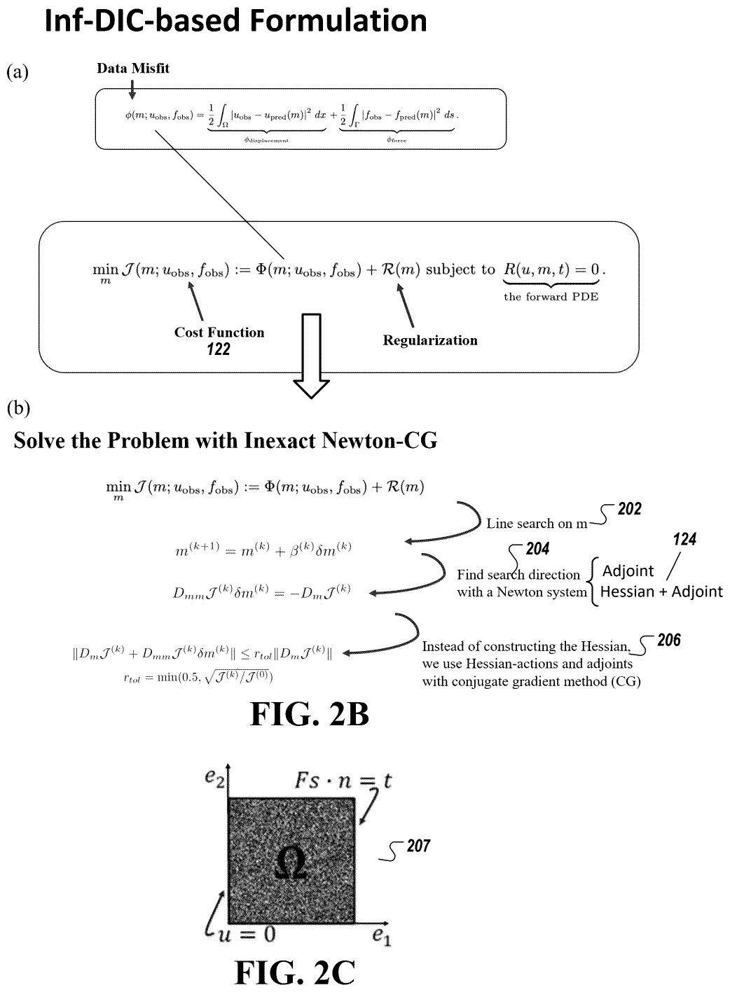

∞-DIC-based Analysis and Defect Detection System (102′. In the example shown in FIG. 1B, a DIC analyzer 140 (shown as “DIC Analysis” 140) is configured to receive the image data 104′ to perform an initial analysis to determine an estimated displacement field 144 from the two or more images 104′. The ∞-dim DIC-based analyzer (shown as 120′), having a similar framework as the ∞-dim IDIC analyzer 120 but configured to operate on an estimated displacement field 144, receives the measurement or estimation of the estimated displacement field 144 from the DIC analysis 140. Similar to the ∞-IDIC-inverse problem solver 120, the ∞-DIC-based inverse problem solver 120′ solves for material field map or data 126 (denoted as m) (e.g., material properties 126′), in a cost function (shown as 122′) over a plurality of iterations, where the cost function 122′ is determined from an error determined between two displacement fields (one from the DIC analysis 140 and the other provided by the physics-based model 128. The cost function 122′ may explicitly depend on the model-derived displacement field 132 (e.g., as u or u_{obs}) and the spatially varying parameter map 126 (e.g., material field map m). In FIG. 1B, the cost function 122′ explicitly depends on the estimated/predicted displacement field data 144 calculated from the DIC analysis 140. In some embodiments, the cost function 122′ is preferably a summation equation of, e.g., (i) a data misfit function having model-derived map 126 (if available from previous iterations), a model-derived displacement estimate 132 (denoted as u) (if model-derived map 126 is available from previous iterations), and mechanical force/work (denoted as f_{obs}) causing the induced displacement of the substrate 110 as input parameters and (ii) a regularization function having map result 126 from previous iterations as input parameter, e.g., as described in relation to FIG. 2B. The ∞-DIC-based inverse problem solver 120′ can continuously solve for the spatially varying parameter field map 126 in the cost function 122 over multiple iterations (in a loop 124) until the map 126 converges (e.g., until adjoint-based gradients and/or Hessian action of the spatially varying parameter field map 126 satisfy a predefined criteria or a stop condition is met (e.g., time out)) by applying a Newtonian-based operator or a gradient-based operator (either comprising a regularization model comprising an L²(Ω) Tikhonov regularization, an H¹(Ω) Tikhonov smoothing regularization, or primal-dual Total Variation regularization) to the estimated and model-derived displacement field (e.g., 144, 132) and the measurement or estimation of the measured induced displacement 106. As discussed above, the Newtonian-based operator (in FIGS. 1i, similar to that in FIG. 1A), or other noted gradient operators, is configured to assess the displacement field data (e.g., 132) in an infinite-dimensional spatial field (e.g., as state variables that are regularized via a regularization model (e.g., L²(Ω) Tikhonov regularization, H¹(Ω) Tikhonov smoothing regularization, and/or primal-dual Total Variation regularization)), e.g., using derivatives (e.g., first and second derivatives) of a gradient of the estimated and model-derived displacement fields (e.g., 144, 132) and the induced displacement of the substrate 110).

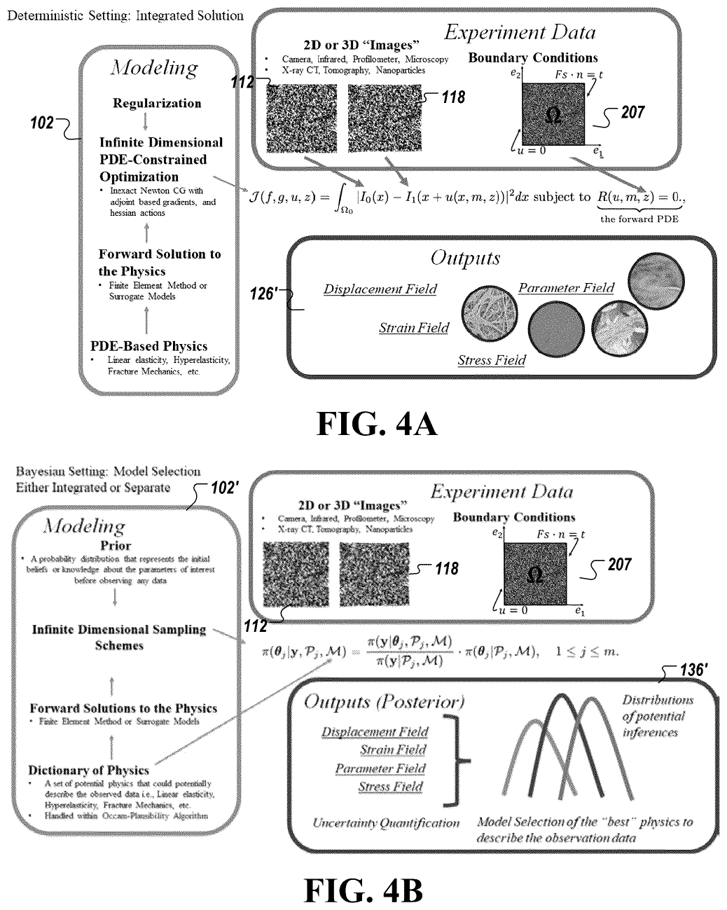

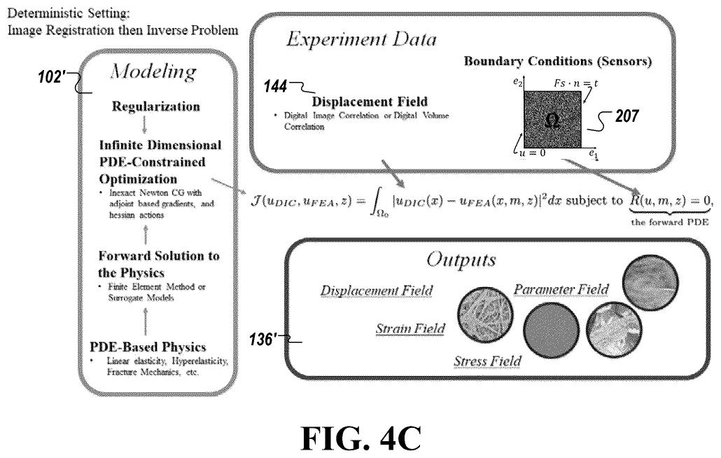

In each iteration, after solving for the spatially varying parameter field map 126, the ∞-DIC-based inverse problem solver 120′ also provides the map 126 comprising material field data as an input to the physics-based model 128 (e.g., FEA or AI/ML). The physics-based model 128 receives the model-derived map 126 with material field data from the ∞-DIC-based inverse problem solver 120′; the model 128 then generates a model-derived displacement estimate 132 from the material field data using a finite element analysis having the revised material field data. The finite element analysis 128 preferably has a pre-defined or pre-established mesh, boundary, and execution conditions, PDE, etc., that can operate on the revised material field data to determine a revised model-derived displacement field to provide back to the ∞-DIC-based inverse problem solver 120′ for further computation (e.g., 122). Example FEA models are described in relation to FIG. 4B.

Once the ∞-dim IDIC inverse problem solver 120′ and physics-based model 128 converges to a solution, the output of the ∞-dim DIC-based inverse problem solver 120′ can be directly or indirectly outputted, via a graphical user interface or report, where the material properties 126′ corresponding to the map 126 having the spatially varying mechanical or material parameter in the spatially-varying field of the substrate 110 can be used for material characterization, defect estimation, and/or mechanical testing and evaluation of the substrate 110, e.g., as described in relation to FIG. 1A.

Indeed, the mechanical or material parameter 126′ can also be provided to a defect estimator 134 for defect estimation. As an example, mechanical and material parameters 126′ may also include and are not limited to stress field, Lame parameters, modulus field, strain field, linear elasticity values, hyperelasticity values, fracture mechanic values, plasticity values, or a combination thereof, for a plurality of spatial-defined locations in the substrate 110. The mechanical and material parameters 126′ also may alternatively include and are not limited to Young modulus, Poisson's ratio, ductility, yield strength, toughness, fatigue, creep, tensile strength, specific modulus, specific strength, shear modulus, shear strength, resilience, plasticity, hardness, fracture toughness, flexural strength, fatigue limit, among others that may be determined per the FEA model, displacement map, or material map.

Physics-basedModel (128). In the examples shown in FIGS. 1A-1, the physics-based model 128 can comprise a finite element analysis or a surrogate model (e.g., AI/ML model) configured to generate a model-derived displacement estimate 132 from the material field data of map 126. In some embodiments, finite element analyses may be performed and then down-selected (or combined), e.g., using artificial intelligence (AI) or machine learning (ML) models.

In other embodiments, the physics-based model 128 can comprise a trained AI model, as a surrogate of finite element analyses, configured to generate a model-derived displacement estimate 132 from the spatially varying parameter field map data 126 (e.g., material field map), where the physics-based model can be selected from the group consisting of a convolutional neural network (CNN), a transformer, a Fourier neural operator, a reduced basis neural operator, or a combination thereof. The trained AI model may be trained using training data, e.g., displacement estimates and material field data generated from FEA analyses or from the operation of the exemplary system (102, 102′) for a set of samples.

### Example ∞-Dim IDIC and ∞-Dim DIC-Based Inverse Problem Solver Operation and Formulation

FIG. 2A shows an ∞-dim IDIC inverse problem solver (e.g., 120) and its implementation/formulation to determine spatially varying parameter field data (e.g., material field data, e.g., 126)) using at least two images (e.g., 112, 118) and a measured/predicted induced displacement (e.g., 106) of the sample/substrate. FIG. 2B shows an ∞-dim DIC-based inverse problem solver and its implementation/formulation to determine spatially varying parameter field data (e.g., material field data, e.g., 126)) using only a displacement field data (e.g., difference/flow/transition/correlation) between the first measured image (shown 112 in FIGS. 1A-1B) and the second measured image 118 in FIGS. 1A-1B determined by DIC analysis (shown as 140 in FIG. 1B).

FIG. 2A, Subpanel (a) shows an ∞-dim IDIC framework to perform inversion analysis of spatially varying parameter fields for a heterogeneous material that handles heterogeneity in an infinite-dimensional framework (rather than a scalar one) and inference for high-dimensional modulus fields and stress fields using directly the at least two images and a measured/predicted induced displacement. By addressing the joint inverse problem within an infinite-dimensional framework, e.g., leveraging adjoint-based gradients and Hessian actions, the exemplary ∞-dim IDIC system and method can effectively account for heterogeneity or defects in the solution. Various regularization methods may be employed to mitigate the ill-posed nature of the inverse problem, with particular emphasis on the efficacy of total variation (TV) in preserving sharp interfaces commonly encountered in materials such as fibers, particles, and grain boundaries. A primal-dual TV formulation may be employed to maintain mesh independence.

The exemplary ∞-dim IDIC system and method can employ (i) ∞-dim IDIC in infinite-dimensional function spaces, enabling the inversion of spatially varying parameter fields, (ii) derivation of adjoint-based gradients and Hessian actions, e.g., for efficient optimization, (iii) regularization methods, e.g., L²(Ω) Tikhonov regularization, H¹(Ω) Tikhonov smoothing regularization and notably primal-dual Total Variation for sharp feature preservation, and (iv) post-processing the inferred modulus and displacement fields to predict stress fields, enabling the identification of stress concentration-based failure mechanisms. The full-field inversion results can be for stress field, Lame parameters, modulus field, strain field, linear elasticity values, hyperelasticity values, fracture mechanical values, material property values, plasticity values, or a combination thereof, among others described or referenced herein, in inferring high-dimensional modulus fields. The exemplary ∞-dim IDIC system and method can be applied to a wide range of materials, including but not limited to tissues, composites, welds, foams, etc.

In FIG. 2A, subpanel (b), the exemplary ∞-dim IDIC system and method employs an infinite-dimensional integrated image registration and parameter identification problem using image data. Specifically, given a model of the underlying physics (e.g., linear elasticity, hyper-elasticity, etc.), the exemplary ∞-dim IDIC system and method formulate a single inverse problem to simultaneously identify the model-derived displacement map m (e.g., 126) and heterogeneous material parameter fields (e.g., model-derived displacement field data u) using images of the undeformed (first state) configuration I₀ (e.g., 112) and deformed (second state) configuration I₁ (e.g., 118) of the body of interest.

In some embodiments, the images are speckled to maximize the information via contrast in pixel values. By constraining the admissible displacements to the governing conservation laws, the resulting coupled inversion and image registration problem can lead to a more accurate reconstruction of the displacement and the parameter fields.

The analysis considers physical models for the governing motion of deforming bodies (e.g., deforming elastic bodies) formulated as partial differential equations (PDEs). Given a physical domain Ω⊂ [symbol] ^{d} (d=2,3) and boundary Γ of a solid body, the PDE model can define the mapping from a spatially varying parameter field m∈ [symbol] (e.g., spatially varying material field m) and the traction t∈ [symbol] to the state variable u∈ [symbol] :=u₀+ [symbol] representing the displacement field (e.g., displacement field u), where [symbol] , [symbol] , [symbol] are the function spaces for parameter, traction, and displacement fields, respectively.

FIG. 2C shows an example schematic of an example setup of boundary conditions 207 (e.g., for both ∞-dim IDIC implementation in FIG. 2A and ∞-dim DIC-based implementation in FIG. 2B). In particular, [symbol] and [symbol] are assumed to be Hilbert spaces such as the Sobolev spaces H^{k}(Ω) and L²(Γ). The state space [symbol] is given as an affine shift of a Hilbert space V by a finite energy lift of any displacement boundary conditions, u₀, where u₀ satisfies the desired Dirichlet boundary conditions and ∥u₀∥V<∝. The PDE model can then be written abstractly per Equation 1.

$$P D E Model : R ( u , m , t ) = 0 \qquad ( Eq . 1 )$$

In Equation 1, the PDE residual, R: [symbol] × [symbol] × [symbol] →V′, is a possibly nonlinear combination of differential operators, and V′ is the (topological) dual of V. Alternatively, the PDE problem can be formulated in its weak form using V as the test space per Equation 2.

$$Find u ∈ 𝒰 such that r ( u , m , t , v ) = 〈 R ( u , m , t ) , v {〉}_{𝒱} = 0 , {∀}_{v} ∈ 𝒱 \qquad ( Eq . 2 )$$

In Equation 2, r: [symbol] × [symbol] × [symbol] ×V→ [symbol] is the weak residual, and [symbol] ·,· [symbol] v denotes the duality pairing between V′ and V. Because r(u, m, t, v) can be linear with respect to the test function V, it can be assumed that the PDE problem is well-posed and admits solution operator u=u(m,t) that is differentiable with respect to the PDE parameters.

In the inverse problem, the inverse problem solver (e.g., ∞-dim IDIC 120) may receive data in the form of two images, I₀ and I₁, (e.g., 112, 118) capturing the undeformed and deformed specimens, respectively. Mathematically, the inverse problem solver (e.g., ∞-dim IDIC 120) considers the two images as functions of spatial coordinates that return the grayscale pixel value of the image at a particular point, e.g., where 0 is black, and 255 is white. Other values or ranges may be used. In particular, images I₀ and I₁ are defined over an image domain Ω_{I}, which is sufficiently large to capture both the undeformed and deformed images. Moreover, consider the space images [symbol] =H¹(Ω_{I}), such that they admit at least one spatial derivative.

The objective of the coupled inversion and registration is then to find the parameter field m (e.g., material field m) such that the predicted displacement yields an image that matches the image of the deformed specimen. This is formulated using the minimization problem per Equations 3 and 4.

$${min}_{m ∈ ℳ , u ∈ 𝒰} 𝒥 ( u , m ; {I}_{0} , {I}_{1} ) : = Φ ( {I}_{0} , {I}_{1} ) + ℛ ( m ) \qquad ( Eq . 3 )$$

$$subject to {\underbrace{R ( u , m , t ) = 0}}_{the forward PDE}$$

$$Φ ( u ; {I}_{0} , {I}_{1} ) = {\int }_{{Ω}_{0}} {\vert {I}_{1} ( x + u ( x ) ) - {I}_{0} ( x ) \vert}^{2} dx \qquad ( Eq . 4 )$$

In Equations 3 and 4, Φ(u; I₀, I₁) is the image misfit, which compares the pixel values of the images over the region of interest (ROI) Ω₀∈Ω, where |·| denotes the magnitude. That is, the misfit is the difference in the two images in function space where the displaced image is pulled-back by the displacement field.

For elliptic PDEs that govern the deformation of solid bodies, the mapping from material parameter fields m to the displacement u tends to be smoothing; that is, highly oscillatory perturbations of m do not significantly affect u. Thus, the inversion of full heterogeneous parameter fields may be inherently ill-posed. To address the ill-posedness, the algorithm (e.g., the ∞-dim IDIC solver 120) employs regularization on the parameter field, [symbol] (m), to the cost functional [symbol] . The regularization acts as a function of the spatially varying parameter map m and is updated at each step.

In FIG. 2B, subpanel (a), the cost function (e.g., 122′), determined by the ∞-dim DIC-based inverse problem solver (e.g., ∞-dim DIC-based solver 120′) in an inverse analysis, is based on minimization of (i) a data misfit function having model-derived map m (if available from previous iterations), a model-derived displacement estimate u_{obs}, and mechanical force/work f_{obs} causing the induced displacement of the substrate 110 as input parameters and (ii) a regularization function based on the spatially varying parameter map m (from previous iterations) as input parameter. In FIG. 2B, subpanel (b), the cost function (e.g., 122′, despite having a different data misfit function compared to FIG. 2A, the cost function 122′ can still be solved using model-derived displacement field data u and spatially varying parameter map m in the same set of operations 202-206 as shown and described in relation FIG. 2A.

Similar to the formulation described in relation to FIG. 2A, the ill-posedness for the ∞-dim DIC-based is in directly identifying the displacement field as determined by an independently evaluated DIC operation. The displacement field in the inverse problem solver (∞-dim DIC-based 120) may also be completely constrained by the underlying PDE solution, u=u(m,t) using regularization that is prescribed on the parameter field to overcome the ill-posedness arising from the desire to invert for heterogeneous material parameters, e.g., as described in relation to FIG. 2A.

Handling the III-posedness of the Inverse Problem. In inverse problems involving high dimensional parameters, it is typical for the PDE operator to be insensitive to certain directions (subspaces) in the parameter space. In such settings, observation data alone may not be sufficient to identify the material parameters in these subspaces. Regularization [symbol] may be introduced to produce a more well-posed problem.

The choice of [symbol] may be based on the prior knowledge about the parameter field and may be tightly related to the choice of a prior distribution on the parameters in Bayesian inference. Thus, the context may motivate the decision of which regularization to use.

The inverse problem solver (e.g., ∞-dim IDIC 120 or ∞-dim DIC-based 120′) may operate on any number of regularization terms, e.g., L²(Ω) Tikhonov regularization, H¹(Ω) Tikhonov smoothing regularization, and notably primal-dual Total Variation.

L² Tikhonov regularization. L² Tikhonov regularization may be employed to penalize the deviation of m from a reference value m̅∈ [symbol] per Equation 5.

$${ℛ}_{{L}^{2}} ( m ) = {γ}_{{L}^{2}} {\int }_{{Ω}_{0}} {\vert m ( x ) - \overline{m} ( x ) \vert}^{2} dx \qquad ( Eq . 5 )$$

For example, m̅(x)=mₙₒₘᵢₙₐₗ, where mₙₒₘᵢₙₐₗ is a nominal value for the material under consideration and may be obtained from a material database.

H¹ Tikhonov regularization. In addition to directly regularizing the values of m, another option is to penalize steeper gradients of m to impose a preference for smooth parameter fields, e.g., via H¹ Tikhonov regularization. H¹ Tikhonov regularization uses an L²(Ω₀) penalization on the gradient per Equation 6.

$${ℛ}_{{H}^{1}} ( m ) = {γ}_{{H}^{1}} {\int }_{{Ω}_{0}} {‖ ∇ m ( x ) ‖}_{2}^{2} dx \qquad ( Eq . 6 )$$

In Equation 6, ∥·∥₂ denotes the Euclidean ( [symbol] ²) norm of a vector in [symbol] ^{d}. The smoothing effect introduced by H¹ regularization may blur sharp edges.

Total variation (TV) regularization. If it is expected a priori that there are sharp edges (i.e., voids, fibers, particles), then total variation (TV) regularization can be introduced. Unlike H¹, TV regularization is defined using an L¹(Ω₀) penalization on the gradient per Equation 7.

$${ℛ}_{TV} ( m ) = {γ}_{TV} {\int }_{{Ω}_{0}} {‖ ∇ m ( x ) ‖}_{2} dx \qquad ( Eq . 7 )$$

Since the L¹(Ω₀) norm is sparsifying, TV regularization may result in piecewise constant parameter fields. However, [symbol] _{TV}(m) is not differentiable when ∇m=0. A common approach to address the issue is by introducing a smoothing parameter, ∈>0, to define a smoothed TV regularization term, e.g., per Equation 8.

$${ℛ}_{TV}^{ϵ} ( m ) = {γ}_{TV}^{ϵ} {\int }_{{Ω}_{0}} \sqrt{{‖ ∇ m ( x ) ‖}_{2}^{2} + ϵ} dx \qquad ( Eq . 8 )$$

The smoothing parameter can smooth the TV functional, making it differentiable, e.g., to lead to a more positive Hessian of [symbol] _{TV}^{∈}. However, this may also produce smooth transitions between piecewise constant regions where the size of the transition regions is related to ∈. Reducing ∈ may bring the approximation [symbol] _{TV}^{∈} closer to [symbol] _{TV}(m), effectively sharpening edges but also making the Hessian less positive.

For the Tikhonov regularization terms, γ_{L}_{²} and γ_{H}_{¹}, there is simply one value to tune, whereas in the case of TV regularization, there are usually two parameters, γ_{TV} and ∈. The choice of E may be crucial, as it may determine the sharpness of the edges in the parameter field, but it also affects the conditioning of the optimization problem.

In some embodiments, ∈ is systematically reduced to sharpen the edges of the parameter field, until the problem becomes ill-conditioned again and the optimization algorithm fails to converge. Moreover, a combination of regularization terms may be used, such as combining L² with H¹ or TV. In such cases, the weighting of the various regularization terms may be implemented as tuning parameters. A common approach is to use a heuristic, such as the L-curve criterion, to determine the optimal values of the regularization parameters. Regardless of the method, the regularization may be tuned to result in a well-posed optimization problem that considers the physical understanding of the problem at hand.

Inexact Newton-CG Method for the Regularized Inverse Problem. Referring to the example shown in FIG. 2A, subpanel B, the incorporation of the regularization terms into the inverse problem can provide a well-posed optimization problem in which an efficient and scalable method may be sought for solving. In an example, the inverse problem solver (e.g., ∞-dim IDIC o120 or ∞-dim DIC-based 120′) may employ a reduced-space approach in which the minimization problem per Equation 3 is solved by explicitly eliminating the PDE constraint R (u,m,t)=0 using the solution operator u=u(m,t). This can lead to an unconstrained minimization problem (e.g., 122) per Equation 9 since the displacement field u directly depends on spatially varying parameter field m (e.g., material filed m) through the solution of the PDE.

$${min}_{m ∈ ℳ} 𝒥 ( u ( m , t ) , m ; {I}_{0} , {I}_{1} ) : = Φ ( u ( m , t ) ; {I}_{0} , {I}_{1} ) + ℛ ( m ) \qquad ( Eq . 9 )$$

The inverse problem solver (e.g., ∞-dim IDIC 120 or ∞-dim DIC-based 120′) may then execute Newton's method (204), or other gradient operators, for solving Equation 9, e.g., to efficiently solve large-scaled inverse problems. Starting at an initial guess, m⁰, the spatially varying parameter field m^{k} is updated at each step for k=1, 2, . . . , per Equation 10.

$${m}^{( k + 1 )} = {m}^{( k )} + {β}^{( k )} δ {m}^{( k )} \qquad ( Eq . 10 )$$

In Equation 10, β^{(k)} is the step size. The search direction δm^{(k)} is determined through the Newton step per Equation 11.

$${D}_{mm} {𝒥}^{( k )} δ {m}^{( k )} = - {D}_{m} {𝒥}^{( k )} \qquad ( Eq . 11 )$$

In Equation 11, Dₘₘ [symbol] ^{(k)} (208) is the Hessian, and Dₘ [symbol] ^{(k)} (210) is the gradient of the (reduced-space) cost functional. Derivatives of the cost function may depend on the PDE solution operator and may be computed efficiently using the adjoint method. However, explicitly constructing the full Hessian can be intractable due to having to solve a pair of linearized forward/adjoint for each column of the matrix. Instead, an Inexact Newton-Conjugate Gradient (INCG) algorithm (206) may be employed that can solve the Newton step problem per Equation 12 using the conjugate gradient (CG) method until the tolerance is satisfied or until negative curvature is detected.

$$‖ {D}_{m} {𝒥}^{( k )} + {D}_{mm} {𝒥}^{( k )} δ {m}^{( k )} ‖ \leq {r}_{tol} ‖ {D}_{m} {𝒥}^{( k )} ‖ \qquad ( Eq . 12 )$$

In Equation 12, the CG algorithm requires only the action of the Hessian on a vector, where each Hessian includes solving a pair of linearized PDEs, thus avoiding the need to explicitly form and invert the Hessian, which is intractable for high-dimensional parameter space.

The inverse problem solver (e.g., ∞-dim IDIC 120 or ∞-dim DIC-based 120′) may use the tolerance, rₜₒₗ=min (0.5, \sqrt{ [symbol]^{(k)}/ [symbol] ⁽⁰⁾}), as this theoretically allows for superlinear convergence in local regimes. Thus, with the chosen CG termination criterion, Inexact Newton-CG can ensure that only a few Hessians are used to solve for the search direction in the global (pre-asymptotic) regime, where the descent does not benefit significantly from Hessian information.

On the other hand, in the regime of local convergence, Equation 11 may be solved to a finer tolerance, incorporating more accurate curvature information to attain superlinear convergence. Nevertheless, using even an approximate Hessian can significantly improve the performance of the algorithm compared to a pure first-order method, such as the steepest descent algorithm, and helps to achieve mesh-independent performance.

Choosing an initial guess for m may be crucial. Ideally, the initial guess may be chosen to be as close to a region of local convergence as possible, e.g., to help reduce the number of iterations required to reach the global regime of convergence. In some embodiments, the initial guess m₀ may be chosen based on the design of the sample and its expected manufacturing result.

The optimization algorithm can converge to a local minimum or can not converge at all. In the context of materials characterization, the initial guess may be set to be a uniform field that represents homogenized material properties (i.e., force divided by sample area). Alternatively, in the context of non-destructive evaluation, the initial guess can be set to the known material properties without nonconformities (voids, cracks, etc.). A benefit of the inverse problem solver (e.g., ∞-dim IDIC or ∞-dim DIC-based 120) is that there is no need to assume there are non-conformities in the material properties as they will naturally arise during inversion.

Derivation of the Adjoints and Hessian-actions for ∞-IDIC. The inverse problem solver (e.g., ∞-dim IDIC 120 or ∞-dim DIC-based 120′) may employ the gradient and Hessians of the cost function (e.g., reduced-space cost function). To compute the gradient of [symbol] , the inverse problem solver (e.g., ∞-dim IDIC 120 or ∞-dim DIC-based 120′) may employ a Lagrangian approach by introducing an adjoint variable, p∈ [symbol] , and a Lagrangian function per Equation 13.

$$ℒ ( u , m , t , p ) = Φ ( u ( m , t ) ; {I}_{0} , {I}_{1} ) + ℛ ( m ) + r ( u , m , t , p ) \qquad ( Eq . 13 )$$

In Equation 13, the gradient is given by setting ∂ₚ [symbol] =0, ∂ᵤ [symbol] =0, such that Dₘ [symbol] =∂ₘ [symbol] , where Dₘ [symbol] is the first derivative of the cost functional with respect to m. For brevity, the arguments to [symbol] is omitted where it is understood that they are to be evaluated at (u,m,t). The forward equation, adjoint equation, and gradient equation may thus be given by Equation Set 14.

$$r ( u , m , t , \tilde{p} ) {∀}_{\tilde{p}} ∈ 𝒱 \qquad ( Eq . 14 a )$$

$$〈 {\partial }_{u} r ( u , m , t , p ) , u {〉}_{𝒱} = - 〈 {\partial }_{u} Φ , \tilde{u} {〉}_{𝒱} {∀}_{\tilde{u}} ∈ 𝒱 \qquad ( Eq . 14 b )$$

$$〈 {D}_{m} 𝒥 , \tilde{m} {〉}_{ℳ} = 〈 {\partial }_{m} ℛ ( m ) , \tilde{m} {〉}_{ℳ} + 〈 {\partial }_{m} r ( u , m , t , p ) , \tilde{m} {〉}_{ℳ} {∀}_{\tilde{m}} ∈ ℳ \qquad ( Eq . 14 c )$$

In Equation Set 14, the misfit's contribution to the adjoint equation may be written as Equation 15.

$$〈 {\partial }_{u} Φ , \tilde{u} {〉}_{v} = {\int }_{{Ω}_{0}} 2 ( {I}_{1} ( x + u ( x ) ) - {I}_{1} ( x ) ) ∇ {I}_{1} ( x + u ( x ) ) \cdot \tilde{u} ( x ) dx {∀}_{\tilde{u}} ∈ 𝒱 \qquad ( Eq . 15 )$$

From Equation 15, the gradient of the cost function can therefore be found by solving the forward and adjoint equations, Equations 14a and 14b, for displacement field u and adjoint p before evaluating the gradient form in Equation 14c for the gradient Dₘ [symbol] . To derive the Hessian, the Hessian Lagrangian may be employed per Equation 16.

$${ℒ}^{H} ( u , m , t , p , \tilde{u} , \tilde{m} , \tilde{p} ) = 〈 {\partial }_{u} ℒ , \hat{u} {〉}_{𝒱} + 〈 {\partial }_{m} ℒ , \hat{m} {〉}_{ℳ} + 〈 {\partial }_{p} ℒ , \hat{p} {〉}_{𝒱} \qquad ( Eq . 16 )$$

Analogously, in Equation 16, ∂ₚ [symbol] ^{H}=0, ∂ₚ [symbol] ^{H}=0 such that [symbol] Dₘₘ [symbol] \hat{m},\tilde{m} [symbol] = [symbol] ∂ₘ [symbol] ^{H}, \tilde{m} [symbol] , where Dₘₘ [symbol] \hat{m} is the Hessian acting in a direction \hat{m}∈ [symbol] . These can give rise to the incremental forward, incremental adjoint, and Hessian equations per Equations 17a-17c.

$$〈 {\partial }_{u} r ( u , m , t , \tilde{p} ) , \tilde{u} {〉}_{𝒱} = - 〈 {\partial }_{m} r ( u , m , t , \tilde{p} ) , \tilde{m} {〉}_{ℳ} {∀}_{\tilde{p}} ∈ 𝒱 \qquad ( Eq . 17 a )$$

$$〈 {\partial }_{u} r ( u , m , t , \hat{p} ) , \tilde{u} {〉}_{𝒱} = - ( 〈 {\partial }_{uu} Φ \hat{u} , \tilde{u} {〉}_{𝒱} + 〈 {\partial }_{mu} r ( u , m , t , p ) \hat{m} , \tilde{u} {〉}_{𝒱} + 〈 {\partial }_{uu} r ( u , m , t , p ) \hat{u} , \tilde{u} {〉}_{𝒱} ) {∀}_{\tilde{u}} ∈ 𝒱 \qquad ( Eq . 17 b )$$

$$〈 {D}_{mm}^{2} 𝒥 \hat{m} , \tilde{m} {〉}_{ℳ} = 〈 {\partial }_{m} ℛ ( m ) \hat{m} , \tilde{m} {〉}_{ℳ} + 〈 {\partial }_{mm} r ( u , m , t , \hat{p} ) \hat{m} , \tilde{m} {〉}_{ℳ} + 〈 {\partial }_{m} r ( u , m , t , \hat{p} ) \tilde{m} , \hat{p} {〉}_{ℳ} + 〈 {\partial }_{um} r ( u , m , t , \hat{p} ) \hat{u} , \tilde{m} {〉}_{ℳ} {∀}_{\tilde{m}} ∈ ℳ \qquad ( Eq . 17 c )$$

The incremental forward Equation 17a may be solved for \hat{p}, the incremental adjoint problem Equation 17b may be solved for û, and the variables may be combined with the displacement field u and adjoint p to give the Hessian of the cost functional acting in the direction of \hat{m} per Equation 17c. Again, the misfit contribution to the incremental adjoint equation may be expressed as Equation 18.

$$〈 {\partial }_{uu} Φ \hat{u} , \tilde{u} {〉}_{𝒱} = {\int }_{{Ω}_{0}} 2 ( {I}_{1} ( x + u ( x ) ) - {I}_{0} ( x ) ) ∇ {I}_{1} ( x + u ( x ) ) \hat{u} \cdot \tilde{u} dx + {\int }_{{Ω}_{0}} 2 ( ∇ {I}_{1} ( x + u ( x ) ) \cdot \hat{u} ) ( ∇ {I}_{1} ( x + u ( x ) ) \cdot \tilde{u} ) dx ∀ \tilde{u} , \tilde{u} ∈ 𝒱 \qquad ( Eq . 18 )$$

In Equation 18, the approximation appears to be accurate when the data misfit I₁(x+u(x))−I₀(x) is small. But, since the approximation may not be the true Hessian, it is not expected that superlinear convergence may be achieved. While a full Hessian could be computed if the second spatial derivative of the image is well-defined, the piecewise constant speckle patterns (e.g., 117 in images 112, 118) may be undefined at the edges of the speckles.

Mesh Independent using Primal-Dual TV. The method introduced by Chan et al. [49], aims to linearize the non-linear term by introducing a dual variable and modifying the Newton algorithm. To employ Primal-Dual TV, the inverse problem solver (e.g., ∞-dim IDIC 120 or ∞-dim DIC-based 120′) may introduce a dual variable w where w=∇m/\sqrt{|∇m|²+∈}.

In the primal-dual approach, a line search may be performed on w in addition to m. At each Newton step, a line search is performed on w in a search direction, ŵ. A backtracking line search on w^{(k+1)} can be performed until w^{(k+1)}·w^{(k+1)}<1. The search direction may be given by Equation 19.

$$\hat{w} = \frac{1}{\sqrt{{\vert ∇ m \vert}^{2} + ϵ}} ( I - A ( m , w ) ) ∇ \hat{m} - w + \frac{∇ m}{\sqrt{{\vert ∇ m \vert}^{2} + ϵ}} \qquad ( Eq . 19 )$$

In Equation 19, A(m,w) may be a matrix defined per Equation 20.

$$A ( m , w ) = \frac{1}{2} w ⊗ \frac{∇ m}{\sqrt{{\vert ∇ m \vert}^{2} + ϵ}} + \frac{1}{2} \frac{∇ m}{\sqrt{{\vert ∇ m \vert}^{2} + ϵ}} ⊗ w \qquad ( Eq . 20 )$$

In Equation 20, once the step direction in w is found, w may be used to update the Hessian of the TV term. The Hessian action for the TV term may be given per Equation 21.

$$〈 {\partial }_{mm} {ℛ}_{TV}^{ϵ} ( m ) \hat{m} , \tilde{m} {〉}_{ℳ} = {γ}_{TV}^{ϵ} {\int }_{Ω} \frac{1}{\sqrt{{\vert ∇ m \vert}^{2} + ϵ}} [ ( I - A ( m , w ) ) ∇ \tilde{m} ] \cdot ∇ \tilde{m} dx \qquad ( Eq . 21 )$$

This is the Hessian action for the TV term in the primal-dual approach. The primal-dual approach avoids the non-linear term by handling the line search (202), e.g., on the dual variable. This method is mesh-independent and may be employed in the Newton operator, e.g., when using TV regularization, among others.

### Example Method of Operation

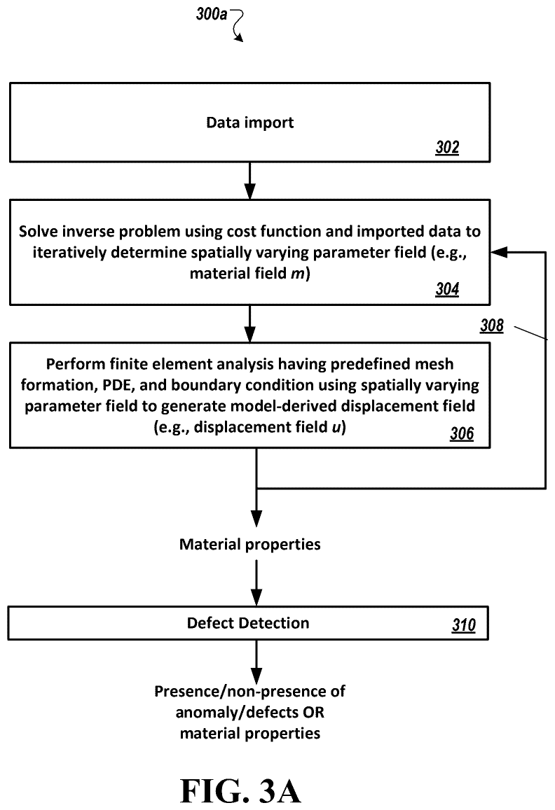

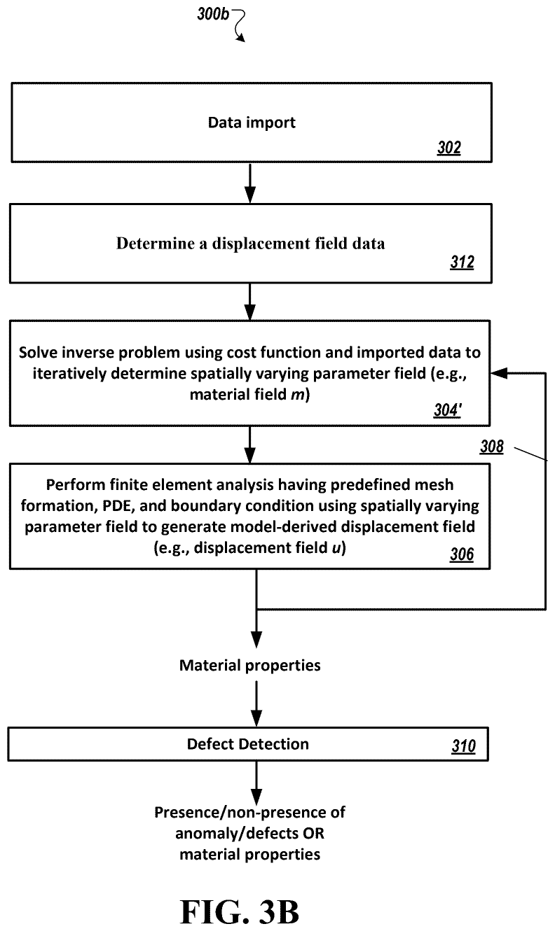

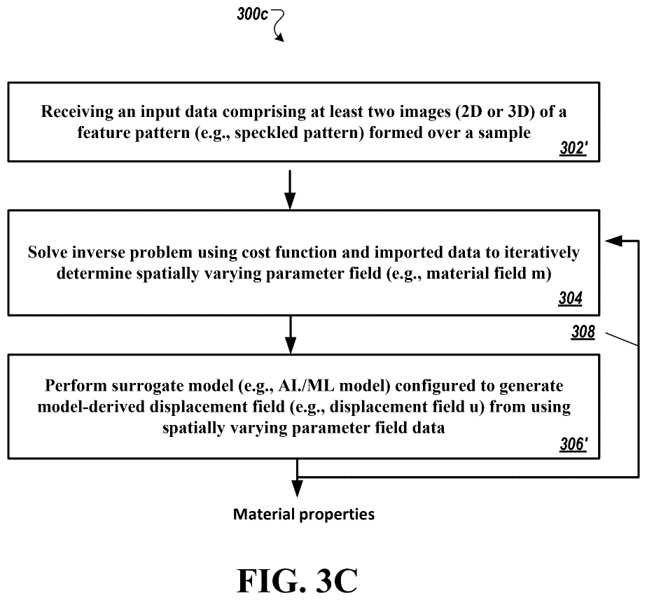

FIGS. 3A-3C show example runtime operation flow and methods of performing inverse-problem analysis that can determine spatially-varying mechanical parameters (such as linear elasticity and hyperelasticity, among others described herein) in a spatially-varying field for the exemplary system, in accordance with an illustrative embodiment.

FIG. 3A shows an example runtime operation flow 300a for the exemplary system, as described in relation to FIGS. 1A and 2A. The method 300a includes importing (302) data (e.g., image data 104 in FIG. 1A, 2A) from an external data source (e.g., data store).

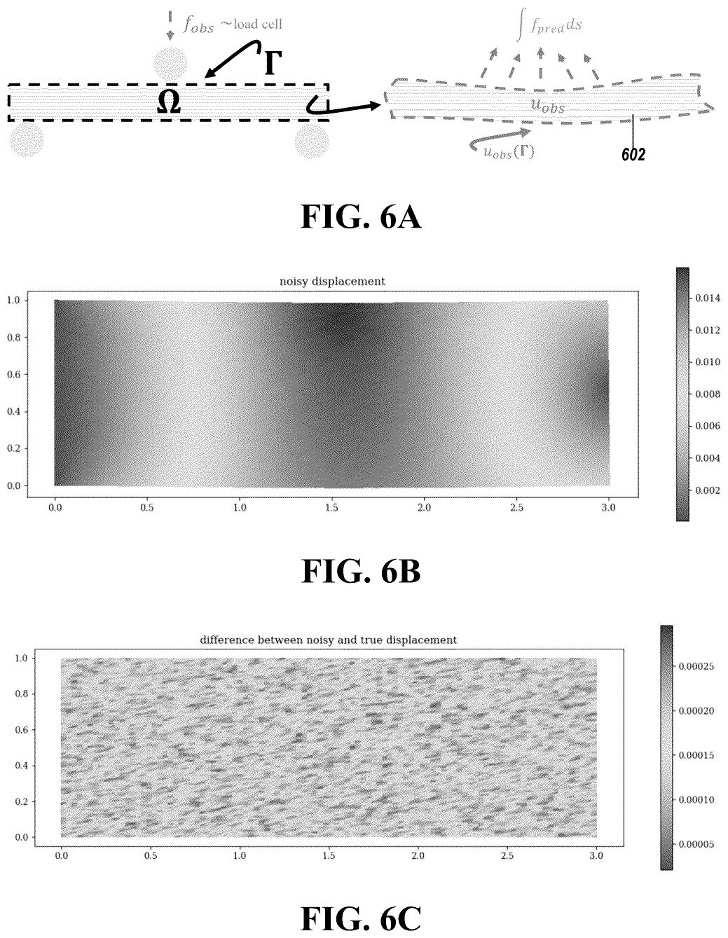

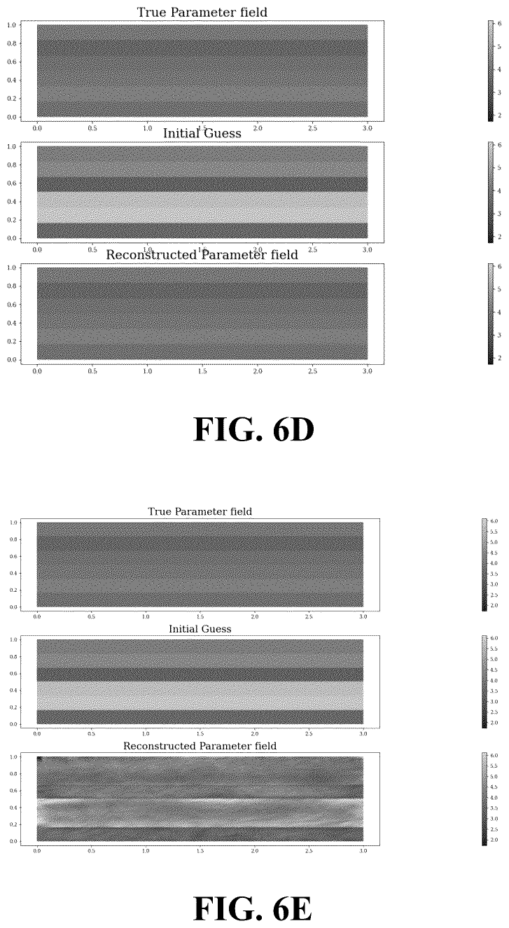

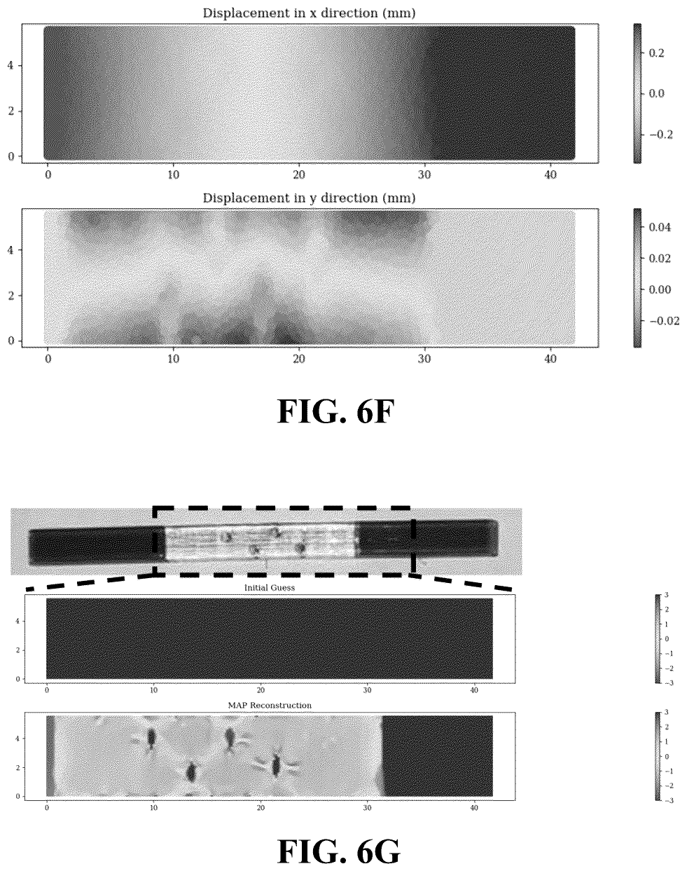

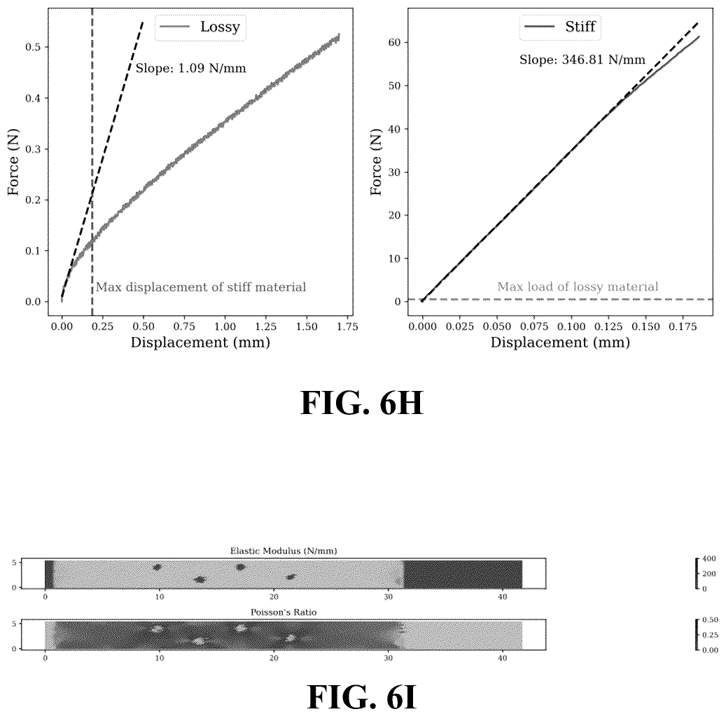

The exemplary method 300a then includes solving (304) an inverse problem using a cost function, e.g., as described in relation to FIGS. 1A and 2A, and the imported data to iteratively determine spatially varying parameter fields (e.g., material field data m). In FIG. 3B, rather than importing the data directly to solve the inverse problem, a DIC analysis is performed (310). An example DIC analysis is provided in relation to FIG. 6A. The method 300b then includes solving (304′) an inverse problem using a cost function, e.g., as described in relation to FIGS. 1B and 2B, and the estimated displacement field data from the DIC analysis to iteratively determine spatially varying parameter fields (e.g., material fields m).

The exemplary method 300a can then perform (306) a finite element analysis that has a predefined mesh formation (derived from the imported data), a partial differential equation (PDE) model, and a boundary condition to determine a model-derived displacement field (e.g., 132).

The method 300a includes solving (308) additional inverse problems (304) using a cost function, to iteratively determine spatially varying parameter field (e.g., material field m) using an error parameter between the model-derived displacement field data derived from the physics-based model and the prior determined displacement field data. In FIG. 3A, the solving (308) may be performed on pixel data derived from the model-derived displacement field data. In FIG. 3B, the solving (308) may be performed based on the displacement field data.

The output of the method 300a can be directly or indirectly outputted via a graphical user interface or report, where the material properties (126′) corresponding to the spatially varying parameter map (e.g., 126) having the spatially varying mechanical or material parameter in the spatially-varying field of the substrate can be used for material characterization, defect estimation, and/or mechanical testing and evaluation of the substrate. Indeed, the mechanical or material parameter can be provided to a defect estimator for defect estimation. As an example, mechanical and material parameters 126′ may include and are not limited to stress field, Lame parameters, modulus field, strain field, linear elasticity values, hyperelasticity values, fracture mechanic values, plasticity values, or a combination thereof, for a plurality of spatial-defined locations in the substrate. The mechanical and material parameters may alternatively include and not limited to Young modulus, Poisson's ratio, ductility, yield strength, toughness, fatigue, creep, tensile strength, specific specific modulus, specific strength, shear modulus, shear strength, resilience, plasticity, hardness, fracture toughness, flexural strength, fatigue limit, among others that may be determined per the FEA model, displacement map, or material map.

The defect estimation (310), e.g., can be an anomaly detector or a threshold detector that can be used to determine and output an indication of the presence/non-presence of anomaly/defects or material properties to reject/pass a part, a batch of the part, or a process associated with the part. In some embodiments, the output (mechanical or material parameter or indication of the presence/non-presence of anomaly/defects) can be used to direct further analysis, e.g., destructive evaluation of the sample.

In some embodiments, the inverse problem analysis employs a Newtonian-based operator that assesses the displacement field data in an infinite-dimensional spatial field as state variables that are regularized via a regularization model (e.g., L²(Ω) Tikhonov regularization, H¹(Ω) Tikhonov smoothing regularization and/or primal-dual Total Variation regularization), e.g., as described in relation to FIG. 1A. Other gradient operators may be used.

In some embodiments, the Newtonian-based operator computes adjoint-based gradients and Hessians in the minimization. In some embodiments, the adjoint-based gradients and Hessians are employed to infer a probability distribution of the plurality of spatially varying mechanical parameters.

The exemplary system and method may employ a dictionary of known models which can each independently be used to solve dimension-independent Bayesian IDIC problems. The Bayesian representations of the inferred material properties can be ranked in how well they describe the observations, via the use of the Bayesian model evidence, to, e.g., allow engineers to find a high-quality material defect reconstruction by additionally taking the underlying PDE model into account. The additional operation can be referred to as the Bayesian model selection using dimension-independent IDIC.

In some embodiments, the two images comprise CCD camera images, infrared camera images, sensor images, profilometer scans, microscopy images (e.g., Scanning, Tunneling, Confocal), x-ray images, or CT scans.

FIGS. 4A and 4B show example implementation of the method of FIGS. 3A, 3B, and 3C.

In FIG. 4A, the physics-based model (e.g., 128) included DPE and finite element analysis to evaluate linear elasticity, hyperelasticity, and fracture mechanics, among others. The output of the (i) inverse problem (e.g., 122) of the ∞-dim IDIC 120 and (ii) physic-based model (e.g., 128) includes displacement field, strain field, stress field, and parameter field. A surrogate model (e.g., AI/ML model) of the physics-based model may be employed, e.g., as described in relation to FIG. 3C. Other parameters as described herein may be employed.

In FIG. 4B, the physics-based model (e.g., 128) included DPE and finite element analysis to evaluate linear elasticity, hyperelasticity, and fracture mechanics, among others. The output of the (i) inverse problem (e.g., 122′) of the ∞-dim DIC-based 120′ and (ii) physic-based model (e.g., 128) includes displacement field, strain field, stress field, and parameter field. A surrogate model (e.g., AI/ML model) of the physics-based model may be employed, e.g., as described in relation to FIG. 3C. Other parameters as described herein may be employed.

AI/ML Surrogates of ∞-dim IDIC or ∞-dim DIC-based operation. To reduce computational costs of the dimension-independent IDIC and its Bayesian formulations, which may be intractable due to the computational costs of the PDE simulations via the finite-element method, neural operator surrogates, e.g., machine learning and AI, may be used to learn the mathematical relationship between the material properties and the resulting displacement fields. The neural operators can determine a displacement field given a modulus field and traction conditions (force applied), e.g., as a surrogate to the finite element method that solves the same problem. The displacement field is then the inverse problem.

The learned representations via a trained AI/ML model can be orders of magnitude faster than the corresponding PDE simulation via the finite element method. The trained AI/ML model can also use dimension-independent information similar to the dimension-independent IDIC method, leading to efficient learning formulations and representations for large-scale PDE problems. With certain AI/ML operations, the ∞-dim IDIC or ∞-dim DIC-based prediction may be performed with near-real-time performance via AI/ML hardware acceleration. A derivative-informed neural operator can be employed to dramatically reduce the computing times of the forward solves (and derivative information for the optimization scheme). The output of the finite element analysis can be used to train the neural operators. The input data is the modulus fields and traction conditions and then the solution data are displacement field solves of the finite element.

FIG. 3C shows an example method 300c of performing inverse-problem analysis using a trained AI model as a surrogate for the physics-based model. The method 300b employs similar operations as that performed in FIG. 3A. Rather than a physics-based model, the method 300b is configured to perform (306′) a surrogate model (e.g., AI/ML model) configured to generate model-derived displacement field (e.g., displacement field u) from using spatially varying parameter field data. The trained AI/ML model, e.g., neural operator, can be trained using outputs of finite element method solves as the ground truth and modulus fields and traction conditions as the input. The training may employ the Adam optimization algorithm or others. The output of the inverse-problem analysis can be employed, as described in relation to FIGS. 3A and 3B.

In some embodiments, the trained AI/ML model may include a Derivative Informed Neural Operator. The “neural operator” can represent the mapping from spatially varying parameter space (e.g., material field data m, e.g., modulus) and pre-defined boundary conditions to a predicted displacement field (the forward solve). The optimization's goal is to discover the modulus field that provides a displacement field that minimizes the cost. An example AI/ML model is described in Haghighat, Ehsan, et al. “A physics-informed deep learning framework for inversion and surrogate modeling in solid mechanics.” Computer Methods in Applied Mechanics and Engineering 379 (2021): 113741.

FIG. 4C shows an example implementation of the Bayesian method described herein. In FIG. 4C, multiple physics-based models (e.g., 128), e.g., each including DPEs and finite element analysis or AI/ML surrogate models, to evaluate linear elasticity, hyperelasticity, and fracture mechanics, among others, are down-selected using Bayesian analysis. The output of the inverse problem (e.g., 122) and physic-based model (e.g., 128) included a displacment field, strain field, stress field, and parameter field. The Bayesian analysis may be based on the distribution of potential references. Other parameters as described herein may be employed.

Machine Learning. The trained AI/ML model can be implemented using one or more artificial intelligence and machine learning operations described herein or others. The term “artificial intelligence” can include any technique that enables one or more computing devices or computing systems (i.e., a machine) to mimic human intelligence. Artificial intelligence (AI) includes but is not limited to knowledge bases, machine learning, representation learning, and deep learning. The term “machine learning” is defined herein to be a subset of AI that enables a machine to acquire knowledge by extracting patterns from raw data. Machine learning techniques include, but are not limited to, logistic regression, support vector machines (SVMs), decision trees, Naïve Bayes classifiers, and artificial neural networks. The term “representation learning” is defined herein to be a subset of machine learning that enables a machine to automatically discover representations needed for feature detection, prediction, or classification from raw data. Representation learning techniques include but are not limited to autoencoders and embeddings. The term “deep learning” is defined herein to be a subset of machine learning that enables a machine to automatically discover representations needed for feature detection, prediction, classification, etc., using layers of processing. Deep learning techniques include but are not limited to artificial neural networks or multilayer perceptron (MLP).

Machine learning models include supervised, semi-supervised, and unsupervised learning models. In a supervised learning model, the model learns a function that maps an input (also known as feature or features) to an output (also known as target) during training with a labeled data set (or dataset). In an unsupervised learning model, the algorithm discovers patterns among data. In a semi-supervised model, the model learns a function that maps an input (also known as a feature or features) to an output (also known as a target) during training with both labeled and unlabeled data.

Neural Networks. An artificial neural network (ANN) is a computing system including a plurality of interconnected neurons (e.g., also referred to as “nodes”). This disclosure contemplates that the nodes can be implemented using a computing device (e.g., a processing unit and memory as described herein). The nodes can be arranged in a plurality of layers, such as an input layer, an output layer, and optionally, one or more hidden layers with different activation functions. An ANN having hidden layers can be referred to as a deep neural network or multilayer perceptron (MLP). Each node is connected to one or more other nodes in the ANN. For example, each layer is made of a plurality of nodes, where each node is connected to all nodes in the previous layer. The nodes in a given layer are not interconnected with one another, i.e., the nodes in a given layer function independently of one another. As used herein, nodes in the input layer receive data from outside of the ANN, nodes in the hidden layer(s) modify the data between the input and output layers, and nodes in the output layer provide the results. Each node is configured to receive an input, implement an activation function (e.g., binary step, linear, sigmoid, tanh, or rectified linear unit (ReLU), and provide an output in accordance with the activation function. Additionally, each node is associated with a respective weight. ANNs are trained with a dataset to maximize or minimize an objective function. In some implementations, the objective function is a cost function, which is a measure of the ANN's performance (e.g., an error such as L1 or L2 loss) during training, and the training algorithm tunes the node weights and/or bias to minimize the cost function. This disclosure contemplates that any algorithm that finds the maximum or minimum of the objective function can be used for training the ANN. Training algorithms for ANNs include but are not limited to backpropagation. It should be understood that an ANN is provided only as an example machine learning model. This disclosure contemplates that the machine learning model can be any supervised learning model, semi-supervised learning model, or unsupervised learning model. Optionally, the machine learning model is a deep learning model. Machine learning models are known in the art and are therefore not described in further detail herein.

A convolutional neural network (CNN) is a type of deep neural network that has been applied, for example, to image analysis applications. Unlike traditional neural networks, each layer in a CNN has a plurality of nodes arranged in three dimensions (width, height, and depth). CNNs can include different types of layers, e.g., convolutional, pooling, and fully-connected (also referred to herein as “dense”) layers. A convolutional layer includes a set of filters and performs the bulk of the computations. A pooling layer is optionally inserted between convolutional layers to reduce the computational power and/or control overfitting (e.g., by downsampling). A fully-connected layer includes neurons, where each neuron is connected to all of the neurons in the previous layer. The layers are stacked similarly to traditional neural networks. GCNNs are CNNs that have been adapted to work on structured datasets such as graphs.

Other Supervised Learning Models. A logistic regression (LR) classifier is a supervised classification model that uses the logistic function to predict the probability of a target, which can be used for classification. LR classifiers are trained with a data set (also referred to herein as a “dataset”) to maximize or minimize an objective function, for example, a measure of the LR classifier's performance (e.g., an error such as L1 or L2 loss), during training. This disclosure contemplates that any algorithm that finds the minimum of the cost function can be used. LR classifiers are known in the art and are therefore not described in further detail herein.

A Naïve Bayes' (NB) classifier is a supervised classification model that is based on Bayes' Theorem, which assumes independence among features (i.e., the presence of one feature in a class is unrelated to the presence of any other features). NB classifiers are trained with a data set by computing the conditional probability distribution of each feature given a label and applying Bayes' Theorem to compute the conditional probability distribution of a label given an observation. NB classifiers are known in the art and are therefore not described in further detail herein.

A k-NN classifier is an unsupervised classification model that classifies new data points based on similarity measures (e.g., distance functions). The k-NN classifiers are trained with a data set (also referred to herein as a “dataset”) to maximize or minimize a measure of the k-NN classifier's performance during training. This disclosure contemplates any algorithm that finds the maximum or minimum. The k-NN classifiers are known in the art and are therefore not described in further detail herein.

### Example DIC Analysis in ∞-Dim DIC-Based Operation

The Digital Image Correlation (DIC) analysis can measure the displacement field, u_{obs}, on the domain Q. During testing, a load cell may measure an observed force, denoted as f_{obs}, which can capture the integral of resultant forces on the top boundary, denoted as Γ, shown in FIG. 6A. FIG. 6A shows an example three-point bending setup with a displacement field known a priori. To measure a spatial distribution of applied loads (f_{obs} in FIG. 6A) can be modeled using (i) Neumann boundary conditions by assuming a distribution of forces on Γ or (ii) modeling a loading fixture as contact conditions. The former may add modeling bias, and the latter may be computationally expensive and challenging to solve in the infinite-dimensional algorithm of the exemplary system.

Instead, a full-displacement field can be assumed as known a priori from a commercial DIC code and a scalar load cell value to determine material properties that best represent the observed data, which is an inverse problem. The inverse problem can be solved through an optimization operation.

In some embodiments, the exemplary system can solve an inverse problem that handles the material parameters as spatially varying fields to discover heterogeneous behavior. The parameter to an observable map (p2o map) in an inverse problem analysis can be defined as a forward problem, which is the solution to a governing PDE model and can solve for the displacement field given a material property field. When given an experimental displacement field, the exemplary system can seek an inversion for the material property field. The exemplary system can define a data misfit, ϕ, with two contributions, the displacement field (ϕ_{displacement}) and resultant force measurement (ϕ_{force}), as shown in Equation 32.

$$ϕ ( m ) = \frac{1}{2} {\int }_{Ω} {\vert {u}_{obs} - {u}_{pred} ( m ) \vert}^{2} dx + \frac{1}{2} {\int }_{Γ} {\vert {f}_{obs} - {u}_{pred} ( m ) \vert}^{2} ds \qquad ( Eq . 32 )$$

The first p2o can map the material properties (varying in space), denoted as m, to the displacement field, denoted as u_{pred}(m). The second p2o can map m to the resultant force on the boundary, f_{pred}(m). The p2o maps are PDE models (e.g., linear elasticity) that can necessitate boundary conditions to solve. The exemplary system can take the boundary of the u_{obs} on F and directly use the data as Dirichlet boundary conditions, which is shown as 602 in FIG. 6A. The inverse problem can be posed as an optimization problem, defined per Equation 33.

$${Min}_{m} J ( m ; {u}_{obs} , {f}_{obs} ) : = Φ ( m ; {u}_{obs} , {f}_{obs} ) + R ( m ) subject to {\underbrace{R ( u , m , t ) = 0}}_{the forward PDE} \qquad ( Eq . 33 )$$

The p2o maps may be smoothing in nature, i.e., oscillatory perturbations of m do not significantly affect u. Moreover, there may be many material property fields that satisfy the data. The inversion of full heterogeneous parameter fields may be inherently ill-posed. To overcome this ill-posedness, regularization can be introduced on the parameter field, denoted as R(m), to the cost functional J. A particular regularization that preserves sharp interfaces to overcome the ill-posedness.

When a well-posed optimization is generated, the exemplary system can use an inexact Newton-CG framework since the second-order technique can scale independently of the mesh discretization. To discover fine features (e.g., voids, interfaces, cracks) in the material, the exemplary system can use finer meshes, which can increase the cost of the forward PDE. If the mesh discretization algorithm is mesh-dependent, the mesh discretization algorithm may increase the number of iterations with a refinement of the mesh, increasing the cost, so the discretization algorithm employed by the exemplary system can preserve mesh independence. Additionally, the exemplary system is configured to use an optimize and then discretize approach. This means that we find the gradient and Hessian in infinite-dimensional function space (pen and paper by forming lagrangian forms) before ultimately discretizing onto a finite element mesh to solve. Other DIC methods may be used.

### Experimental Results and Additional Examples

A study was conducted to develop and evaluate the exemplary non-destructive image registration and inverse problem analysis system and method as described in relation to FIGS. 1-4. The study confirmed the exemplary system and method can provide inferred spatially varying material parameters corresponding to stress fields that can be subsequently used for failure prediction mechanisms, such as von Mises stresses, among others described herein. Existing and conventional methods do not generally evaluate material heterogeneity. The exemplary system and method can beneficially be employed for the prediction of stress concentration-based failure mechanisms by capturing the spatial relationship between strain and modulus, among others.

Example Method of Generating the Synthetic Setting. Two PDEs are illustrated, including linear and hyperelasticity, to demonstrate the effectiveness of the exemplary inversion method for both linear and nonlinear constitutive relationships over a range of deformation magnitudes. Using a variety of realistic spatially varying material properties such as voids, stiff particles, and Voronoi tesselations, the inverse problem solver (e.g., ∞-dim IDIC or ∞-dim DIC-based operation 120) can solve the underlying PDEs and generate noise-corrupted synthetic image data. The inverse problem solver (e.g., ∞-dim IDIC or ∞dim-DIC-based 120) can then invert for the true material parameter fields from the synthetic data.

Linear Elasticity. Physical domains Ω₀=(0,1)² may be considered that are given by unit squares. The strong form of the linear elasticity PDE over Do may be given by Equation 34.

$$∇ \cdot ( σ ( u ) ) = 0 in Ω \qquad ( Eq . 34 )$$

$$u = 0 on {Γ}_{L}$$

$$σ ( u ) \cdot n = t on {Γ}_{R}$$

$$σ ( u ) \cdot n = 0 on {Γ}_{T} ⋃ {Γ}_{B}$$

In Equation 34, a fixed displacement condition may be prescribed on the left boundary Γ_{L}, a traction t on the right boundary Γ_{R}, and traction-free boundary conditions on top and bottom boundaries, Γ_{T} and Γ_{B}. Here, the stress tensor may be given by σ(u)=λ∇·uI+2με(u), where

$$ε ( u ) = \frac{1}{2} ( ∇ u + ∇ {u}^{T} ) ,$$

and λ and μ are the Lamé parameters. The traction may be written in terms of its normal and shear components per Equation 35.

$$t = {t}_{normal} {e}_{1} + {t}_{shear} {e}_{2} \qquad ( Eq . 35 )$$

In Equation 35, the Lame parameters may be related to Young's modulus, E, and Poisson's ratio, v, per Equation 36.

$$λ = \frac{Ev}{( 1 + v ) ( 1 - 2 v )} , μ = \frac{E}{2 ( 1 + v )} \qquad ( Eq . 36 )$$

For the inverse problem, the Poisson's ratio may be fixed, e.g., at v=0.3, and Young's modulus, E(x) is the field of interest. To prevent the modulus from becoming negative, the algorithm may impose E(x)=e^{m}(x) to ensure that E(x)>0 where x∈Ω₀ is a spatial coordinate, and the quantity of interest being inverted for is m. Using the notation H_{L}¹(Ω)={u∈H¹(Ω): u|_{Γ}_{_{L}}=0}, the variational form of the PDE written in the form of Equation 2 may be read as find u∈H_{L}¹(Ω) such that for all v∈H_{L}¹(Ω) per Equation 37.

$${r}_{LE} ( u , m , t , v ) := {\int }_{Ω} σ ( u \cdot m ) : ε ( v ) dx - {\int }_{{Γ}_{L}} t \cdot vds = 0 \qquad ( Eq . 37 )$$

Hyperelasticity. In addition to linear elasticity, a hyperelastic material model, which is commonly used to model rubber-like materials, biological tissues, and other materials that undergo large deformations, may be employed. The stress-strain relationship is non-linear in nature; the inverse problem solver (e.g., ∞-dim IDIC or ∞-dim DIC-based 120) should operate for image data arising from large deformations. A neo-Hookean model or Saint Venant-Kirchhoff model could be employed, among others.

In hyperelasticity, the internal forces that develop in the material may be derived from a strain energy function, W=W(X, C(X)), where C(X)=F(X)^{T}F(X) is the right Cauchy-Green deformation tensor, and F(X)=I+∇u(X) is the deformation gradient. For the neo-Hookean model, the strain energy function is given by Equation 38.

$$W ( X , C ( X ) ) = \frac{μ ( X )}{2} ( tr ( C ( X ) ) - 3 ) - μ ( X ) ln J ( X ) + \frac{λ ( X )}{2} {ln}^{2} J ( X ) \qquad ( Eq . 38 )$$

In Equation 38, μ and λ are the Lamé parameters, tr(C) is the trace of C, and J=det(F) is the determinant of the deformation gradient. The strong form of hyperelasticity PDE may then be given by Equation Set 39.

$$∇ \cdot ( F ( u ) S ( u ) ) = 0 in Ω \qquad ( Eq . Set 39 )$$

$$u = 0 on {Γ}_{L}$$

$$F ( u ) S ( u ) \cdot n = t on {Γ}_{R}$$

$$F ( u ) S ( u ) \cdot n = 0 on {Γ}_{T} ⋃ {Γ}_{B}$$

In Equation Set 39, S(X)=2∂W/∂C(X) is the second Piola-Kirchhoff stress tensor and the applied traction t is the same as in Equation 40.

$${r}_{HS} ( u , m , t , v ) = {\int }_{Ω} S ( u \cdot m ) : ε ( v ) dx - {\int }_{{Γ}_{R}} t \cdot vds = 0 \qquad ( Eq . 40 )$$

Synthetic Data Generation (Creating Speckled Images). To generate the synthetic data for the inverse problem, the use of the defined PDEs may be used. The assumption of a prior agreement between the understanding of the physics and the observed data can lead to committing what is known as an “inverse crime.” Each numerical result is derived using the same PDE that is subsequently utilized to inform the inverse problem. Frankly, this is a common practice in the field of inverse problems, and it is used to test the performance of the algorithm. Synthetic data is generated by solving the PDEs for the forward problem and saving speckled images before and after deformation. The speckled images are then used as the observational data in the subsequent inverse problem. In an actual experiment, the images would be captured using a camera, or similar sensor while the speckled specimen is under load.

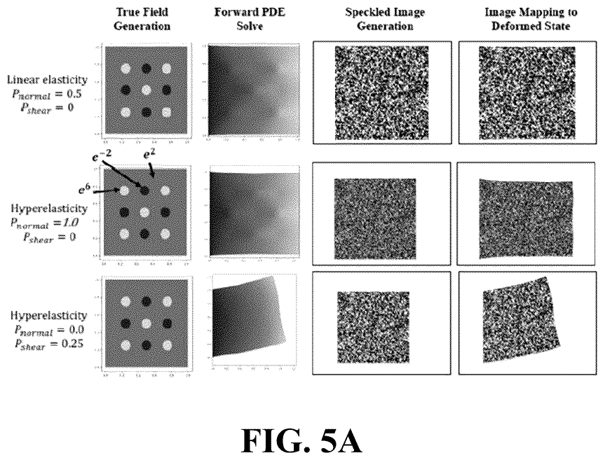

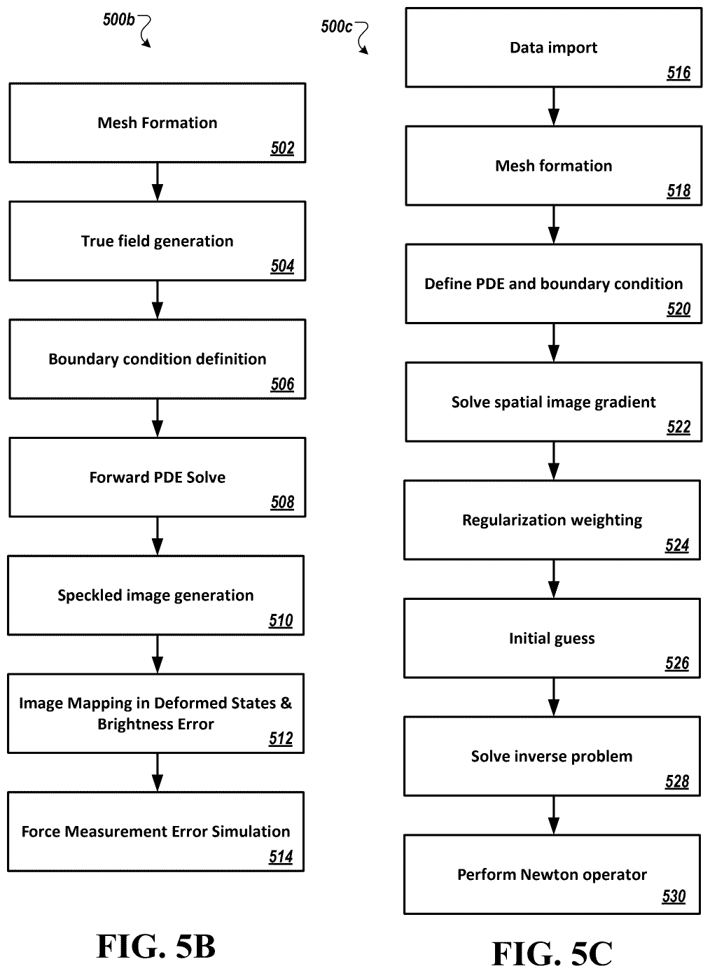

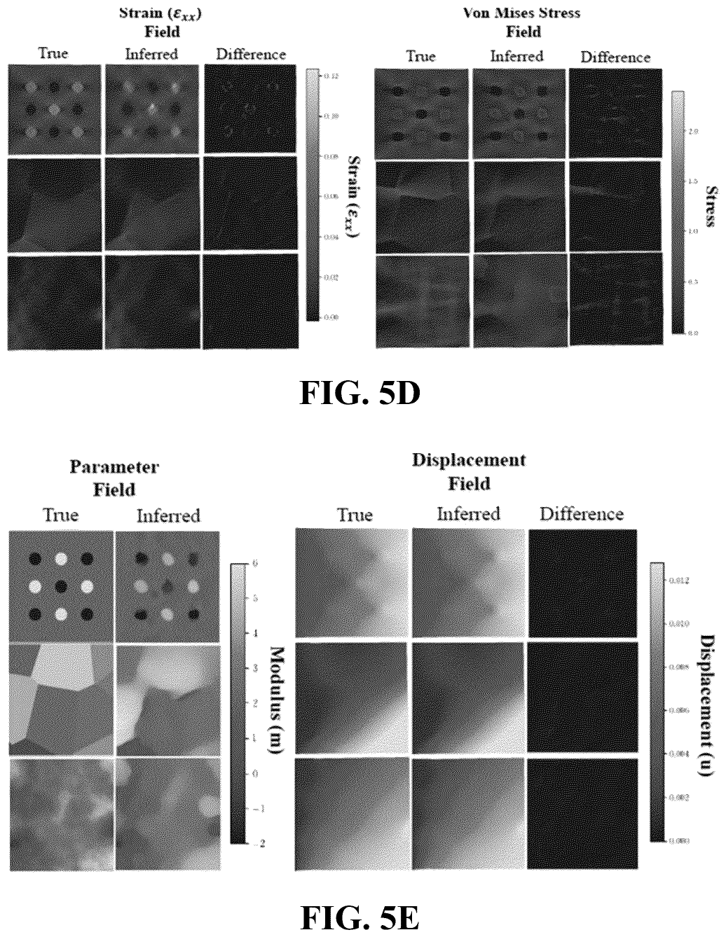

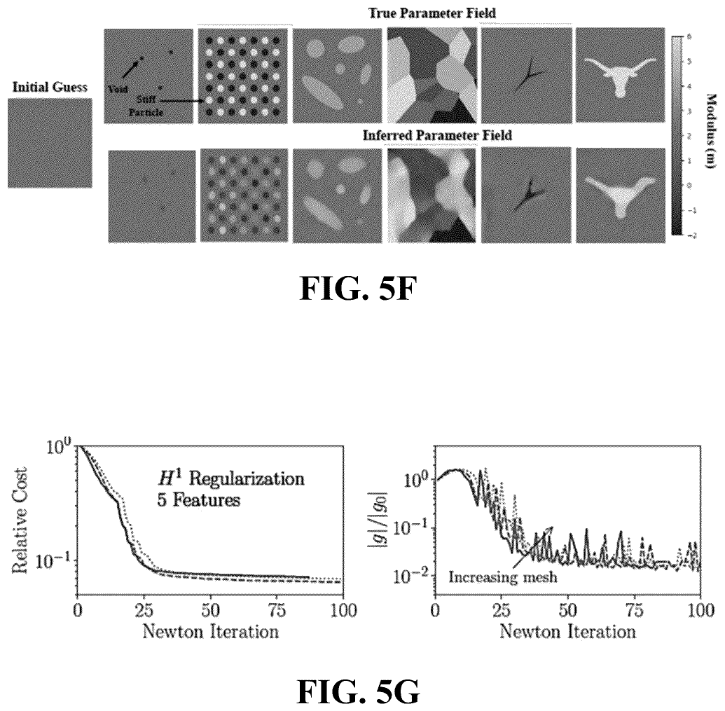

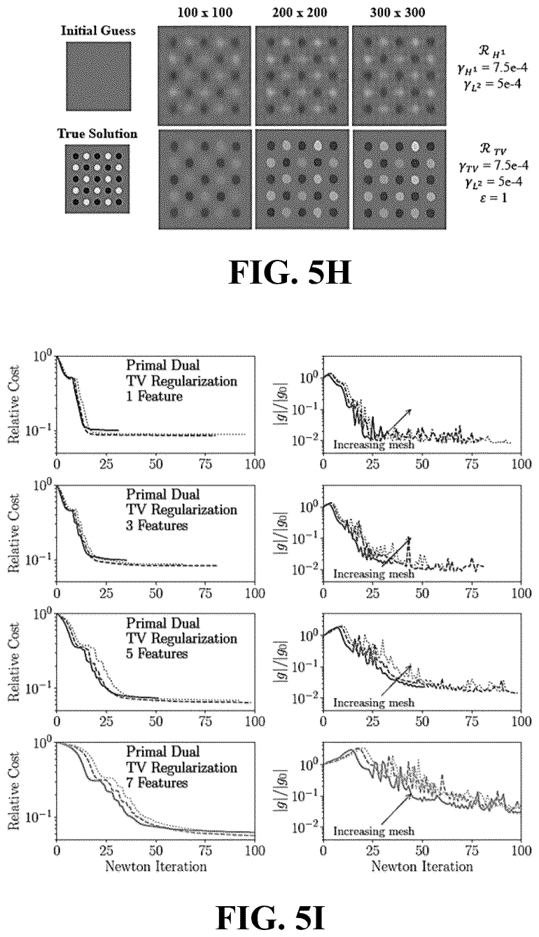

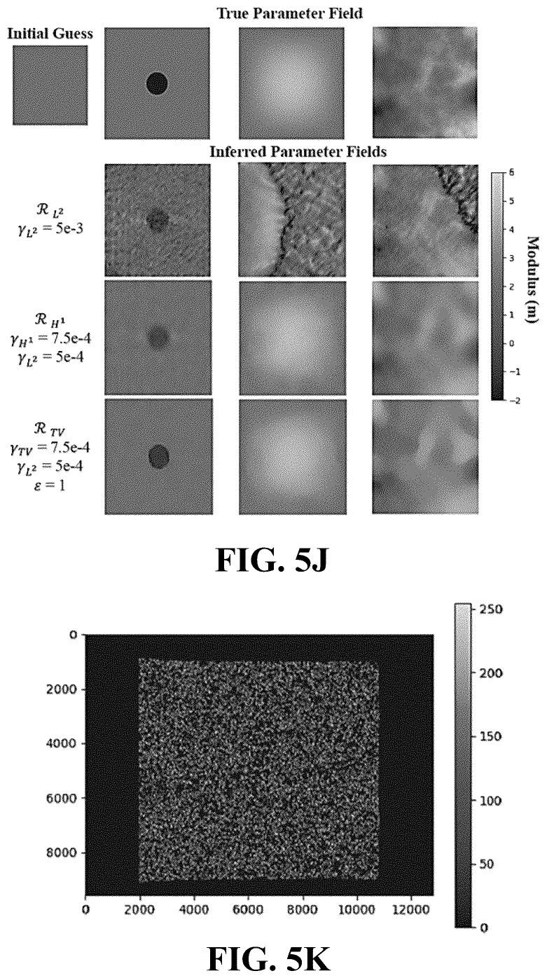

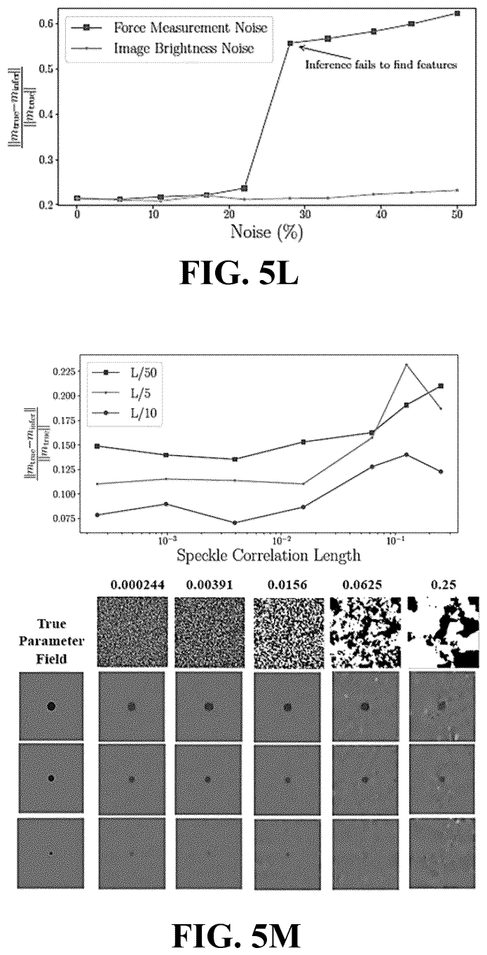

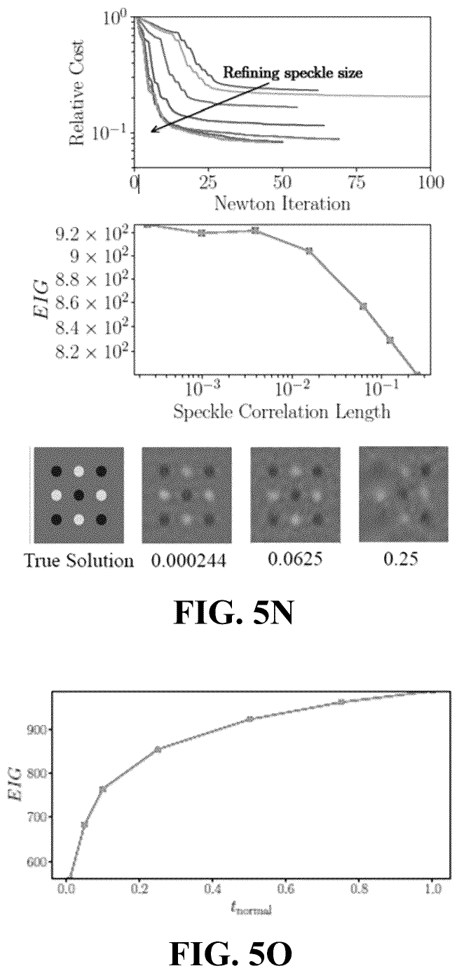

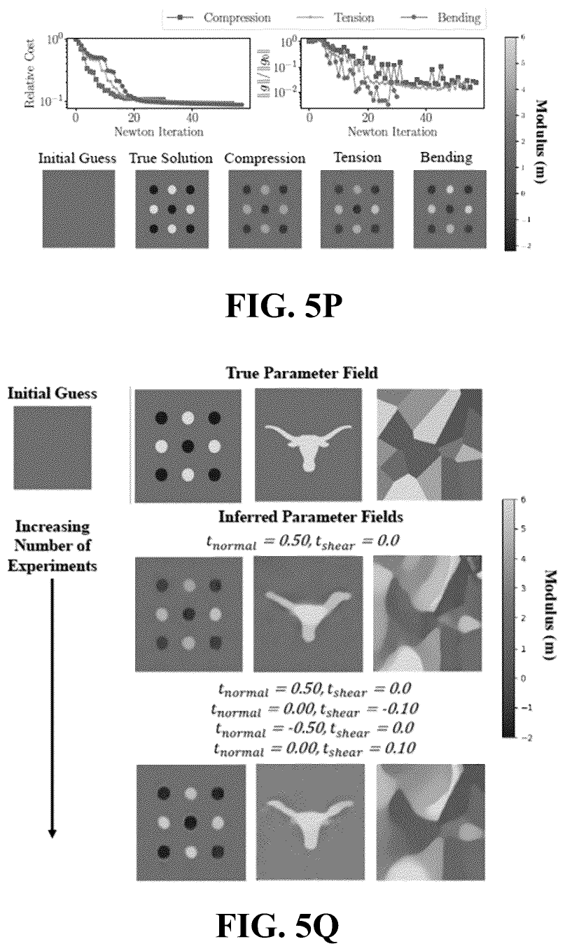

FIG. 5A shows a schematic of the synthetic data generation process employed in the study. FIG. 5B shows a method to perform the synthetic data generation process employed in the study, the method includes: mesh formation (502), true field generation (504), boundary condition definition (506), forward PDE solving (508), speckle image generation (510), image mapping (512) in deformed states and brightness error, and force measurement error simulation (514).

Mesh Formation (502): Construct a mesh of size 500×500, where 500 is the number of elements in the mesh. The mesh is used to approximate Ω₀ via linear Lagrangian triangular elements to form finite element spaces [symbol] ^{h}∈ [symbol] and [symbol] ^{h}∈ [symbol] . The parameter and state space are 1,002,001 and 502,002 dimensions, respectively.

True Field Generation (504): Generate a true field, mₜᵣᵤₑ(x), that represents the true material model. This field is used to generate Young's modulus, E(x)=e^{m}^{ₜᵣᵤₑ}^{(x)}, and the Poisson's ratio v(x)=0.35. The true field is generated through a handful of strategies geared toward representing complex material fields. These include (i) varying lossy (E(m)=e⁻²) and stiff (E(m)=e⁶) particles on a medium (E(m)=e²), (ii) generating Voronoi tesselations, (iii) generating a bump field with a single bump in the center of the domain with smooth decay to the edges, (iv) generating spatial fields from images, and (v) generating an isotropic Gaussian random field with defined correlation lengths.

Boundary Conditions Definition (506): Define the traction condition, t, on the right boundary, Γ_{right}, by determining the forces, P, and the Dirichlet boundary condition, u=0, on the left boundary, Γ_{left}. The Neumann boundary condition is defined as t=0 on the top and bottom boundaries, Γₜₒₚ and Γ_{bottom}. The example boundary conditions are shown in FIG. 2C.

ForwardPDE Solve (508): Solve the forward PDE for the true material model to obtain the true displacement field uₜᵣᵤₑ(x) and the true stress field σₜᵣᵤₑ(x).

Speckled Image Generation (510): Generate a speckled image existing in the discretized parameter space [symbol] by taking a sample i from a bilaplacian prior. The correlation length of the bilaplacian prior [symbol] can regulate the respective correlation length of the speckles. As the speckles in DIC are black (0) or white (255), thresholding is applied. This is done by projecting i to a function space, [symbol] ^{h}, and transforming for the image, I(x), using Equation 41.

$$I ( x ) = 255 - 255 tanh ( 100 i ( x ) + 1 )$$

Image Mapping in Deformed States & Brightness Error (512): Map the simulated speckle to both the reference and deformed states, thereby generating the reference image (I₀) and the deformed image (I₁). A modified version of the FEniCS plotting tool operating in displacement mode is used. Instead of representing displacement, the colormap represents the grayscale speckle values. The displaced image is corrupted with white noise, i.e., N˜ [symbol] (0, σ²), where sigma is the noise level multiplied by the maximum pixel value to simulate image brightness error. Notably, in practice, the material domain, Ω₀, is smaller than the image domain, Ω₁. To simulate, the images can be saved as .png files with additional white space around the material domain.

Force Measurement Error Simulation (514): To mimic errors in force measurement data and corrupt the traction condition. For instance, if the true force value is tₙₒᵣₘₐₗ=10, the corrupted value is tₙₒᵣₘₐₗ=9.5, given a 5% error in a tensile measurement. The corrupted value is saved to a .txt file for subsequent use in the inverse problem.

### Example Inverse Problem Analysis for Material Identification

FIG. 5C shows an example inverse problem analysis performed in the study. The inverse problem can be reduced/optimized for runtime to the method described in relation to FIGS. 3A, 3B, and 3C. In the example shown in FIG. 5C, the operation for solving the inverse problem includes:

Data Import (516): Import the corrupted reference and deformed images, I₀ and v, respectively, and the corrupted force measurements. The force measurements are used to determine the traction condition, t, on the right boundary, Γ_{right}.

Mesh Formation (518): Construct a mesh of size N×N where N is the number of elements in the mesh. The mesh is used to proximate Ω₀ via linear Lagrangian triangular elements to form finite element spaces [symbol] ^{h}∈ [symbol] and [symbol] ^{h}∈ [symbol] N will vary depending on the experiment, particularly for demonstrating mesh-independent performance.

Define the PDE and Boundary Conditions (520): The study defined the PDE and boundary conditions for the inverse problem. The PDE is the same as the forward problem, but the material parameter, E(x), is unknown. The Poisson's ration v(x)=0.35∀x∈Ω₀. The boundary conditions are the same as the forward problem, but the right traction condition, t, was determined from the corrupted force measurements.

Solve for the Spatial Image Gradients (522): The study solved for the spatial image gradients, ∇I₀ and ∇I₁.

Decide the Regularization Weighting (524): The weighting Γ was chosen for the regularization, regardless of the choice of regularization. The study determined the weighting via trial and error as well as using a heuristic such as the L-curve method.

Initial Guess (526): It is assumed that the initial guess for the material parameter, E(x), is a constant value across the domain. For example, the constant value could be taken from a material datasheet.

Solve the inverse problem (528): The study used the open-source software hIPPYlib to solve the inverse problem [50]. hIPPYlib is a software library for large-scale deterministic and Bayesian inverse problems. The library is built on top of the finite element library FEniCS and the optimization library PETSc. hIPPYlib provides a high-level interface for handling the infinite-dimensional inverse problem, where we provide the necessary ingredients.

Perform Newton operator (530): The study solved the inverse problem using Newton-CG where the relative and absolute tolerances were set to 1e⁻³ and 1e⁻⁴, respectively. The maximum number of iterations was set to 150. The maximum number of CG iterations was set to 10 based on observation of improved performance. The backtracking was limited to 25 iterations, and the Armijo condition was set to 1e⁻⁴. In the case for the primal dual, a special Newton CG algorithm was used where the dual variable was updated in sync with the parameter search directions.

### Post-Processing the Inverse Problem for Strain and Stress (Visualization)

In DIC experiments, it is customary to post-process the displacement field to a strain field using the Green-Lagrange strain relationships. The approach can yield strain fields, e.g., εₓₓ, ε_{yy}, and ε_{xy}, which are commonly utilized in presenting DIC results.

In some embodiments, N_{corr}, an open-source DIC software, may be employed to perform the methodology [51]. The strain fields can be visualized as spatially varying scalar fields, representing the deformation of the material by selecting one direction in the strain tensor. FIG. 5D shows an example visualization in the post-processing of the displacement field.

As an example, the visualization can focus on the strain in the x direction, denoted as εₓₓ, which aligns with tₙₒᵣₘₐₗ for linear elasticity. Computationally, this may achieved by isolating the component in the x direction, calculated per Equation 42.

$$ε = \frac{1}{2} ( ∇ u + ∇ {u}^{T} ) \qquad ( Eq . 42 )$$

Strain fields have been used to gain insight into part behavior during loading. Yet, materials and structures are often designed to stress criteria. In the setting of heterogeneous materials, the stress field is different from the strain field. Only in the setting of a homogeneous material does the stress field directly align with the strain field. A common stress criterion is the Von Mises stress which is used to predict yielding in materials under uniaxial tension. For linear elasticity, the Von Mises stress field σᵥₘ can be calculated per Equation 43.

$${σ}_{vm} = λ tr ( ε ) + 2 με \qquad ( Eq . 43 )$$

In Equation 31, λ and μ are the Lame parameters. They are related to E(m) and v through the relations in Equation 24. The Von Mises stress is a scalar field that represents the stress state of the material and is convenient for visualization.

The post-processing results are shown for linear elasticity only, but similar techniques could be used for the hyperelasticity case. FIG. 5D shows the strain and stress fields for the same features as in FIG. 5E.

In FIG. 5D, the first case is the 3×3 grid of alternating stiff and lossy regions. The strain field shows limited deformation in the stiff interfaces and large deformation in the lossy. At the edges of the lossy regions, the difference in inferred and true is likely due to the sharpness of the interface. The difference may also be attributed to the noise and ill-posedness of the inverse problem. The stress field may show the behavior of interest as the concentration occurs in the surrounding medium around the voids. If failure were to occur, it is expected that this region would be at high risk.

The second case shows simulated grain boundaries of a metal microstructure. The strain field captures the largest strain occurring in the grain with the lowest modulus. Moreover, at regions of high modulus, the strain is minimal. The stress concentrates at interfaces between grains, which is expected but is a fantastic result for the algorithm. The inferred stress field correctly finds this behavior.

The third case of an isotropic Gaussian random field shows the stress concentrations around regions of increased modulus. This is a complex microstructure to infer, but the exemplary ∞-dim IDIC system and method can capture the general trend of the strain and stress fields. The stress field can beneficially show the concentration band across the center of the domain, e.g., due to modulus variations in this region.

Indeed, the integrated infinite-dimensional algorithm can provide outputs that can be visualized as stress fields by inference of both the spatially varying modulus and displacement, e.g., to illustrate heterogeneity in material properties allows this natural extension to strain and stress fields. Previous works in DIC are limited by handling the parameter field in low dimensions, typically just 1-2 dimensions, whereas for the shown inverse problems handled on a 100×100 mesh, the algorithm can invert for 40,401 parameter values (FIG. 6). Mathieu et al., for example, can infer two scalar values when using the Ramberg-Osgood law [10], Roux et al. infer eight scalar values when demonstrating the use of multiple experiments in a single inversion [11], and Gras et al. inferred three parameters for a complex woven composite [52]. Instead of handling each parameter as a single scalar, the inverse problem solver (e.g., ∞-dim IDIC 120 or ∞-dim DIC-based 120′) can infer them as fields to allow to heterogeneity to arise and to naturally extend to stress states. Experimental data later show the mesh-independent performance of the exemplary method, where a 200×200 and 300×300 mesh are shown to solve the inverse problem with 160,801 and 361,201 parameter values, respectively. Other mesh size may be used, e.g., 100×100, 200×200, 300×300, 400×400, 500×500, 600×600, 700×700, 800×800, 900×900, 1000×1000. In some embodiments, the mesh size is larger than 1000×1000. In some embodiments, the mesh is configured in other shapes, e.g., rectangle.

Example #1—∞-dim IDIC Non-Destructive Evaluation. The instant study illustrated the exemplary system and method through nondestructive evaluation problems for solids where the observation data is displacement field data obtained from differences in deformed and undeformed states of the material, painted with speckle patterns. Traditional DIC, in contrast, may derive displacement field data via mere statistical correlation in differences in speckle-patterned images [3], which may lead to cascading errors in the inversion, as the displacements obtained from these algorithms may not obey the underlying physics. Integrated DIC (previously coined as IDIC), introduced by Benard, Hild, and Roux, overcame the issue by constraining the displacements to follow the governing equations of the deformation process [4]. IDIC in that formulation, however, inverts for material properties as homogeneous constants and not heterogeneous spatial fields [5].

The instant study overcame these issues by re-formulating the prior IDIC approach in function space by modeling the image data and the material properties as infinite-dimensional spatial fields alongside the state variable (e.g., strain) to arrive a distinct operation to prior IDIC. Since the material properties are now formally infinite-dimensional fields that can lead to significant ill-posedness, the instant study employed regularization models, such as L²(Ω) Tikhonov regularization, H¹(Ω) Tikhonov regularization for smooth parameter reconstruction, and (primal-dual) total variation (TV) for reconstruction of sharp features. The modeling reformulations allow for the derivation of a scalable and efficient Newton method, and other gradient operators, for the solution of the corresponding inverse problems.

Via numerical results, the instant study demonstrated the performance of the exemplary ∞-dim IDIC in considering linear elastic and Neo-Hookean hyperelastic models. The study demonstrated that ∞-dim IDIC can recover spatially-varying material properties with remarkable accuracy and sharpness; moreover the exemplary algorithms exhibit mesh-independent convergence properties and superior robustness to observational and loading noise compared to existing methods. The findings show that the inference can depend on the loading conditions, which can be exploited by incorporating multiple experiments in a single ∞-dim IDIC inverse problem.

An important consequence of ∞-dim IDIC is the inferred spatially varying material parameters corresponding to the stress fields. This paves the way for leveraging failure prediction mechanisms, such as von Mises stresses. Unlike existing methods that overlook material heterogeneity, our approach empowers the prediction of stress concentration-based failure mechanisms by capturing the spatial relationship between strain and modulus.

NumericalResults. The study investigated the effectiveness of the exemplary algorithm using synthetically generated data. In particular, the study considered data generated from two example PDEs—linear elasticity and hyperelasticity—to assess the effectiveness of the exemplary inversion method for both linear and nonlinear constitutive relationships over a range of deformation magnitudes. Using a variety of realistic spatially varying material properties such as voids, stiff particles, and Voronoi tesselations, the study solved the underlying PDEs and generated noise-corrupted synthetic image data. The study then attempted to invert the true material parameter fields from the synthetic data.

Having established the process of data generation, the study demonstrated the examples of inversions for PDE systems and post-processing of the Linear Elasticity examples for stress states. A selection of example inversions is presented in FIG. 5E, illustrating the inference of complex material fields for linear elasticity.

The results stem from a straightforward tensile experiment with tₙₒᵣₘₐₗ=0.20, corresponding to approximately ˜2% strain. An example of the deformed state is shown in FIG. 3A, showing a sample having deformed minimally. For simplicity, a known and fixed Poisson's ratio of v=0.35 was assumed, though the inverse problem could also infer this material parameter. To mimic real-world conditions more accurately, the study introduced 10% and 5% noise to the image brightness and force measurements, respectively. Moreover, the inverse problem provides a force applied tₙₒᵣₘₐₗ=0.19 instead of the true value of tₙₒᵣₘₐₗ=0.20.

The study solved the inverse problem using the primal-dual total variation formulation with parameters (γ_{L}_{²}=5e⁻⁸, γ_{TV}=1e⁻⁶) on a mesh of size 100×100, with a speckle correlation length of 0.01.

FIG. 5D shows the results. The first showcased result depicts a grid pattern consisting of alternating stiff and void regions. Here, the material parameter is expressed as E(x)=e^{m(x)}, with voids simulated by m(x)=−2, stiff regions by m(x)=6, and the majority of the domain by m(x)=2. Despite a significant variation in features spanning four magnitudes, the inverse problem successfully inferred the spatial parameters. While the inferred features may not precisely match the true modulus distribution, the algorithm was observed to adeptly capture the general spatial trend. Furthermore, the inferred displacement field closely aligns with the ground truth.

The second showcased result exhibited a Voronoi tessellation, symbolic of grain boundaries in a metal microstructure. The inferred field effectively captured the sharp interfaces between grains, demonstrating the capability of total variation regularization to preserve sharp features and infer solutions across discontinuities.

Finally, an isotropic Gaussian random field with a small correlation length around 2 is presented. While total variation regularization favors smooth solutions, the results show the algorithm in be able to infer the general spatial distribution of the material parameters. Despite discrepancies between the inferred and true parameter fields, the overall spatial distribution is faithfully captured, and the displacement fields exhibit good agreement.

The study designed the cost function to minimize the pulled-back difference between images, motivating the discovery of a displacement field that best aligns with observations. Even with a noticeable difference in modulus fields, convergence was achieved once the inferred displacement field sufficiently represented reality, even if the precise modulus was not exactly reproduced. Simply put, once the modulus inference sufficiently could explain the displacement field, the algorithm was observed to converge. Moreover, the synthetic image data was corrupted with noise to mimic real-world conditions, and the inverse problem was informed of a slightly incorrect force measurement. This could be another reason for the modulus field to not perfectly match the true field.

In addition to linear elasticity, the study evaluated the inversions utilizing a nonlinear partial differential equation (PDE) for hyperelasticity. The problem presented increased difficulty due to higher deformations (approximately ˜5% strain) and nonlinear dynamics, rendering it a more challenging inverse problem. FIG. 5F presents results for six cases of complex modulus fields, with inference conducted starting from the same initial guess of m(x)=2. The synthetic images and force measurement were corrupted with 10% and 5% noise, respectively.

In FIG. 5F, the first case features tiny lossy regions (m(x)=−2) with a radius of 0.02, accounting for 1/50 of the domain length. Despite their size, the inference successfully detected the voids while conserving sharp interfaces. Indeed, the exemplary ∞-dim IDIC algorithm appears to be able to infer small features with high contrast in modulus.

In the second case, the study examined a 7×7 grid of alternating void and stiff features. The inference aptly represented the spatial distribution by preserving edges. Similar to the case in linear elasticity, the algorithm captured the general trend of the modulus field, even if the precise values are not perfectly reproduced. Similarly, the displacement field was sufficiently reproduced by the inferred modulus field, satisfying the observation data.

The third test case explored features of varying geometries and sizes, with the inference demonstrating precise capture of the spatial distribution. The algorithm was shown to be capable of inferring complex material fields with sharp interfaces, varying geometries, and sizes, even under large deformations. The fourth case employed a Voronoi tessellation. Despite its complex material distribution and sharp interfaces, the inference accurately discerned the features. Similarly, the displacement field was well-represented, aligning closely with the true field. The two test cases show that the Newton-CG algorithm with derivative information can handle modulus fields with a variety of features and sizes. The fifth case introduces a thin, sharp, branched crack, showcasing the inference's capability to capture such intricate features. This is particularly relevant for applications in non-destructive evaluation, where the algorithm can identify and characterize cracks in materials.

Mesh-independent Performance. The study evaluated the Mesh independent performance of the algorithm in whether optimization would scale with the refinement of the mesh. The study expected increasing the mesh to improve the resolution of features in the inference and potentially the accuracy of the results at the expense of the computational cost, e.g., via a more expensive forward solve of the PDE at each optimization step.

A potential consequence of the mesh-independent performance is that regularization weighting may not need to be changed for varying mesh.

FIG. 5G demonstrates the mesh-independent performance of the exemplary method for H¹ regularization on the parameter where the mesh increased from 100×100, 200×200 to 300×300 for a tensile experiment using 5×5 features on hyperelastic medium with ˜5% strain. 10% and 5% noise applied to the image brightness and force measurements, respectively. The speckle correlation length was 0.01.

The results show that both the relative cost reduction and normalized gradient norm behaved consistently among mesh sizes. The chaotic behavior in the gradient norm may be attributed to the influence of the speckle as both the gradient and Gauss-Newton Hessian include the difference in the images. The finer mesh likely represented the speckle pattern better, leading to different gradients, although the general behavior is consistent.

In H¹, there was a single weighting term to tune, whereas for TV, there were two. Minimizing the E term appeared to sharpen the preservation of interfaces and is important to tune. FIG. 5H demonstrates the inference for varied meshes using H¹ and TV.

In FIG. 5H, as the mesh increased, the number of parameters was inverted from 40, 401 to 160, 801 and 361, 201 for 100×100, 200×200, and 300×300, respectively. The results showed a slight improvement with an increasing mesh. The speckle pattern is likely better represented on the finer mesh as well, leading to more of the observation data being incorporated into the inverse problem.

FIG. 5I demonstrates the mesh-independent performance for varying mesh sizes for the Hyperelasticity problem using the primal-dual TV formulation.

Previously, it was shown that the algorithm is mesh-independent for H1 regularization but also show mesh-independence for TV regularization when the primal dual formulation is used. The number of features in mₜᵣᵤₑ varied from 1 to 3×3 to 5×5 to 7×7 while the mesh varied from 100×100, 200×200 to 300×300 for each mₜᵣᵤₑ. It is clear from the results that the algorithm performed independently of the mesh size and feature size. The relative cost reduction and normalized gradient norm were consistent among the varying mesh sizes. Varying the number of features in mₜᵣᵤₑ leads to different convergence behavior as the observational data changes with the number of features. Within each feature size, the algorithm performed consistently. The regularization weighting was not changed for the varying mesh sizes nor the varying features. As the number of features increased, the cost took more iterations to decrease as the problem was more difficult. Each experiment started at the same initial guess of m(x)=2, but with more features, this initial guess is further from the true field. Ultimately, each experiment converges in a mesh-independent manner.

Choice of Regularization. While the algorithm can perform mesh independently for both H¹ and TV regularization, the choice of regularization may be tailored to the specifics of the problem at hand. In scenarios characterized by sharp interfaces (e.g., particles, voids, fibers, etc.), TV regularization can be used for its ability to preserve such interfaces effectively. Gaussian random field may alternatively be used, e.g., for non-shart interfaces. Many materials lack sharp interfaces and are more likely to exhibit smooth transitions in material properties. In such cases, H¹ regularization may be more appropriate.

The study evaluated the efficacy of L², H¹, and TV regularization methods. FIG. 5J illustrates the outcomes for three distinct mₜᵣᵤₑ scenarios: a void inclusion, a bump function, and a Gaussian random field.

Both H¹ and TV regularization were able to successfully identify features, albeit with varying degrees of smoothing. The results showed TV regularization preserving sharp interfaces, as evidenced by its performance with the void inclusion scenario. Meanwhile, H¹ regularization tends to produce similarly smooth inferences without preferring sharp interfaces, which may be desirable in certain contexts.

H¹ regularization appeared to outperform TV regularization in scenarios involving Gaussian random fields, showcasing the importance of adapting the regularization to different problem settings. The observations underscore the significance of selecting an appropriate regularization method tailored to the characteristics of the problem under investigation.

The results in FIG. 5J show that L² regularization can perform inadequately despite considerable tuning efforts for the weighting parameter, yielding noisy and inaccurate inferences incapable of identifying material features. It may still be applicable in certain instances.

Influence of Noise Error in the Inverse Problem. The study evaluated the effects of noise and error on the accuracy of the inferred results. Firstly, the study changed the image brightness between the reference and deformed states by changing illumination during testing. Synthetically, this can be modeled as normal perturbations to the image field in the deformed state. The study added a random perturbation with a standard deviation varying from null (no noise) to 127.5 (50% noise) to the deformed image. FIG. 5K shows a resulting image pattern with image brightness noise added to the deformed image.

Secondly, the study evaluated when the measurement of the boundary conditions is not perfect, e.g., the traction conditions at the boundary due to the experimental setup limitations or inherent testing procedures. To consider this synthetically, the study applied error to the boundary condition used in the inverse problem, ranging from 0% to 50% error by multiplying the true measurement by (1−e_{force}) where e_{force} is the error in force measurements to effectively underestimate the true force applied to the boundary. To consider the sources of error, the study applied the error independently, and the alternate source was kept at 0% error. FIG. 5L shows the results.

In FIG. 5L, it is evident that image brightness noise does not impact the exemplary method to infer a correct solution. At 50% brightness noise, the inference maintained 20% accuracy, likely because the modulus values in mₜᵣᵤₑ range over four magnitudes, and the inference discovers a sufficiently large/small enough modulus to represent the displacement field.

FIG. 5L also shows that above 25% error in the force measurement, the inference fails to find the spatial distribution of the features. This is likely due to the error in the force measurement being too large for the optimization to discover a modulus field that results in a displacement field that satisfies the two images. Instead, the resultant inference is over 60% different from the true solution. The numerical results show the exemplary method to be robust to error in the force measurements. Experimental results show that it is important to have accurate force measurements to achieve accurate results.

Speckle Size Influences Information Gain and Feature Size. The study evaluated the influence of the speckle sizes and feature sizes. The study used the speckle pattern during DIC to provide a contrast for comparison between the reference and deformed images. There can be many methods to generate speckle patterns in practice (e.g., spray paint, airbrush, stamping, etc.), and it is of interest to understand how the speckle pattern can influence the inference in high dimensions, particularly when the feature size is on similar length scales to the speckle size.

The synthetic speckle is a bilaplacian prior with a tunable correlation length. The correlation length was reduced from 0.25 to 0.000244, as shown in FIG. 5M, while a single feature was reduced from L/5 to L/50 where the length of the domain L=1.

In FIG. 5M, when the correlation length, 0.25, is larger than the feature size, 0.20 (L/5), the inference was able to discover the feature, although there is noticeable noise surrounding the feature. This result illustrates that the exemplary method is able to infer the correct solution even when the speckle size is sufficiently smaller than the feature size. The noisy solution likely contributed to 10% noise in the image brightness and 5% noise in the force measurements. When the speckle correlation length is large, there is inherently less data to infer the feature which reduces the robustness to noise. Whereas, as the correlation length reduces to 0.0625, the inference was able to discover the feature with less noise, and then below 0.0156, the inference was able to discover the feature with minimal to no noise. The solution was around 12% accuracy at this point while representing the spatial distribution of the feature very well. The information was hidden within the edges of the speckle pattern, which provided the contrast for the DIC algorithm during comparison. Reducing the correlation length increased the number of features in the speckle pattern, providing additional edges for the algorithm to compare.

Furthermore, reducing the feature size to L/10 and L/50 showed that the inference similarly improves with refining the speckle pattern. The L/10 case was able to infer the feature with minimal noise at a correlation length of 0.0156, while the L/50 case was able to infer the feature with minimal noise at a correlation length of 0.0039. Reducing the speckle size was suggested to improve the inference of smaller feature sizes.

The study also considered the mesh size. While the experiments were conducted on a 100×100 mesh, it was expected that the inference would improve with a finer mesh. Notably, at a feature size of L/50, the mesh size was in the same order as the feature size. Regardless, the exemplary method was able to infer the correct modulus distribution using sufficient speckle correlation lengths to provide the necessary data for the inverse problem.

The study also examined the correlation between speckle size and fidelity in solving the inverse problem. FIG. 5N shows an investigation of a 3×3 feature size on a 100×100 mesh while varying the speckle size from 0.25 to 0.000244, with the number of features held constant. In the experiment, the study used an H¹ regularization to solve the inverse problem. One notable discovery was that refining the speckle size led to a more significant and rapid reduction in the relative cost. This means that a smaller speckle correlation length not only can lead to a more accurate inference but requires fewer Newton iterations to reach convergence.

The study performed further analysis to better understand the relationship using tools from Bayesian inverse problems to calculate an expected information gain (EIG) heuristic.

Given a sample of the posterior distribution, the EIG is a measure of the information gained from the data. The study assumed that the inference solution from the deterministic problem is a sample from the posterior distribution. First, a Hessian action was formed from the data misfit components only. The eigenvalues of the Hessian action were then determined using the double pass algorithm, per Equation 44.

$${H}_{misfit} {v}_{i} = {λ}_{i} {Γ}_{prior}^{- 1} {v}_{i} \qquad ( Eq . 44 )$$

In Equation 44, Γₚᵣᵢₒᵣ is the prior covariance matrix. In the experiment, the study used H¹ regularization as the prior covariance was not well-defined for TV. The EIG is related to the eigenvalues of the prior conditioned data misfit Hessian per Equation 45.

$$EIG = \frac{1}{2} log det ( I + H ) = \frac{1}{2} {\sum }_{i = 1}^{N} ( 1 + {λ}_{i} ) \qquad ( Eq . 45 )$$

Notably, Equation 36 holds for linear parameters to observable maps as well as nonlinear employed in the exemplary method. Moreover, the EIG is a heuristic and not a true measure of the information gained. Instead, it is purely a useful tool for comparing the speckle correlation lengths. FIG. 5N demonstrates that as the speckle size was refined, the EIG increased until it began to plateau around a correlation length of 0.0156. This aligned with the observation in FIG. 5M that the inference was able to discover the feature with minimal noise at the same correlation length.

Creating extremely fine speckle patterns may not be practical in the real world. From the experimentation, it appears that once the speckle pattern is refined around two magnitudes smaller than the image size, the information gain per reduction is minimal.

Varying Experiment Boundary Conditions. The study evaluated the effect of the boundary conditions on the inference performance of the exemplary algorithm and observed that the additional deformation improves the inference and that increasing the force and increasing the displacement of the speckle pattern can result in an increase in the EIG of the inverse problem. The inference solution can change as the traction condition varies from compression, tension and bending.

In FIG. 5O, the applied normal force, tₙₒᵣₘₐₗ, of the synthetic images was increased, and the subsequent inference demonstrated that additional deformation improves the inference. The number of features was held constant at 3×3 while the speckle size was varied. Here, 0% noise was applied in order to not corrupt the eigenvalues. An H¹ regularization was used, similar to the EIG analysis for speckle size.

It can be shown in FIG. 5O that as the applied force increased, the EIG increased, likely as the additional deformation provided more information to the inverse problem. The EIG is a heuristic and not a true measure of the information gained. It is purely a tool for demonstrating the observation that additional deformation improves the inference. This appears to be intuitive as the additional deformation provides more information about the inverse problem and reduces the number of possible solutions. For example, under small loads (e.g., 0.1), the EIG is low, and it is likely that the displacement field can be recreated with multiple solutions. However, as the load increases, the EIG increases, and the number of possible solutions decreases. Namely, the modulus fields that can recreate the observed displacement field are refined.

Indeed, the exemplary algorithm appears to be robust to large deformations. Often, in practice, DIC algorithms are limited to small deformations due to the statistical nature of the algorithm. This is typically solved by performing continuation across images to the final deformed state. However, it is observed that the prior understanding of deformation mechanisms (i.e., PDE) in the inverse problem allows for the inference of large deformations without the need for continuation.

In addition to increasing the load magnitude, the study evaluated traction conditions by varying them. FIG. 5P shows inference solutions for compression (tₙₒᵣₘₐₗ=−0.50), tension (tₙₒᵣₘₐₗ=0.50), and bending (tₙₒᵣₘₐₗ=−0.25). The error compared to the true solution, ∥mₜᵣᵤₑ−m_{infer}∥/∥mₜᵣᵤₑ∥, was observed to be 0.233, 0.219, and 0.218 for compression, tension and bending, respectively. Indeed, the observed displacement of the speckle in compression appears to be less than that of tension and bending, likely due to the nature of the loading condition. Additionally, the relative cost and gradient norm appear to reduce slower for compression than the other loading conditions. According to FIG. 5P, bending appears to reduce the quickest. Moreover, the bending condition appears to provide maximum information at the top of the domain where the sample is in tension. This aligns with the observation that tension is more informative than compression.

The study showed that increasing the force, and increasing the displacement of the speckle pattern can increase the EIG of the inverse problem. Moreover, the study showed that the inference solution changes as the traction condition varies from compression, tension, and bending.

Analysis Using Multiple Experiments. The study additionally evaluated the coupling of multiple experiments into a single inverse problem, showing improvements in the inference by providing more information to the inverse problem and reducing the number of possible solutions.

Neggers et al. inferred five isotropic elastic parameters by considering multiple experiments in an IDIC formulation [11], showing that incorporating multiple experiments into a single inverse problem can improve the inference.

Here, the study employed a cost functional for ∞-dim IDIC as set as a sum over the experiments per Equation 46.

$$ℒ ( u , m , z , p ) = ( \frac{1}{{N}_{exp}} {\sum }_{i = 1}^{{N}_{exp}} Φ ( u ; {I}_{0 , i} , {I}_{0 , i} ) ) + ℛ ( m ) + r ( u , m , z , p ) \qquad ( Eq . 46 )$$

In Equation 46, Nₑₓₚ is the number of experiments. Similarly, the forward, adjoint, and gradient equations can become a sum over the experiments. Furthermore, the incremental forward, incremental adjoint, and incremental gradient can be summed over the experiments. Including the 1/Nₑₓₚ ensures that the regularization weighting is consistent from a single experiment. To demonstrate the effectiveness of coupling multiple experiments, three mₜᵣᵤₑ were generated, as shown in FIG. 5Q, with 10% and 5% noise applied to the image brightness and force measurements, respectively.

The inverse problem was solved using the primal-dual total variation formulation (γ_{L}_{²}=5e⁻⁶, γ_{TV}=7.5e⁻⁴) with a mesh size of 100×100, and the speckle correlation length is 0.01.

First, the inverse problem was handled for a single tension (tₙₒᵣₘₐₗ=0.50) experiment. Secondly, the inverse problem was solved for four experiments simultaneously: tension (tₙₒᵣₘₐₗ=0.50), compression tₙₒᵣₘₐₗ=−0.50), downwards bending (tₙₒᵣₘₐₗ=−0.10), and upwards bending (tₙₒᵣₘₐₗ=0.10). Visual comparison between the single and multiple experiment inferences show that the multiple experiment inference is more similar to the true solution. For the 3×3 feature, both the stiff and void regions better match the true solution's modulus.

Moreover, for the longhorn, the ears begin to appear, and both horns are sharpened. The face of the longhorn appears more symmetric as well. Lastly, a Voronoi tessellation is shown where the features sharpen with additional experiments. The study observed there to be multiple smaller features that did not appear in the single experiment inference, but that appeared in the multiple experiment. The introduction of multiple experiments further reinforces the intuition that more displacement of the speckle restricts the set of solutions that can be inferred, resulting in a more accurate solution.

Example #2—Two-way ∞-dim DIC-based NDE. The study also developed and evaluated the two-way embodiment of the exemplary system.

Synthetic Inversion. Table 1 shows the configuration for the synthetic data generation in the experiment.

TABLE 1

| Component/Operation | Details |
|---|---|
| Forward PDE | Non-linear neo-Hookean hyperelasticity |
| Domain | 3 × 1 mm |
| Force Observed | 0.35 (N/mm) |
| Discretization | 300 × 300 Lagrangian elements |
| Noise | 2% error as normal perturbations |
| Boundary conditions | Fixed Dirichlet on left, rollers on right, |
| | Gaussian distributed force on top. |

Within FEniCS [54](i.e., a computing platform to solve PDE using finite element analysis (FEA), the study solved the forward p2o map for a given true parameter field. The resultant displacement field was corrupted with noise and was treated as the experimental DIC data. FIGS. 6B-6C show the noisy displacement field (experimental data) and the noise, respectively. Additionally, the experimental force measurement was also perturbed by 2% noise. The initial guess was taken to be a laminate with random modulus predictions for each layer.

Using the synthetic data approach, the study also showed an inversion using the total variation regularization. The problem of interest was a laminate with piecewise constant properties. FIG. 6D shows the inverse result using total variation (i.e., piecewise constant regularization), wherein the scale bar is the log(m). The study successfully used an initial guess that assumes a laminate structure, since total variation preferred piecewise constant with distinct interfaces. The relative L2 error between the true and reconstructed parameter fields was 0.029. The inverted parameter predicted a resultant force with a 10-8 relative error to the true force.

To illustrate the importance of using a regularization method, FIG. 6E shows an inversion result using rudimentary Tikhonov regularization (L2 minimization with respect to a nominal value, taken to be zero). As shown, Tikhonov regularization resulted in a relative error of 0.22. The study committed “inverse crime” in FIG. 6E by generating the synthetic data using the same constitutive model with which the inverse problem was done. Even though the study corrupted the data with noise, these models did not represent real-world experiments. However, the result in FIG. 6E was still promising for the ability to invert for lamina properties in beam bending with this the exemplary system and method, which was straightforward to implement with experimental data since the study did not require Neumann boundary conditions and only the displacement field from DIC, plus the load cell value.

Tensile Experiments. The study also compared the inversions between using total variation (e.g., piecewise constant regularization) and rudimentary regularization (e.g., L2 Tikhonov). The first method, total variation, did not incorporate the force into the data misfit and instead directly posed the load cell as a uniformly distributed Neumann boundary condition. The second method, rudimentary regularization (e.g., Tikhonov regularization), used the approach discussed above. The samples were manufactured using a Polyjet printer with two polymeric resins: the red polymer was a stiff plastic, and the clear polymer was a lossy rubber. The study chose these two resins because the as-printed sample's modulus corresponded to the color. The study tested the samples using a micro tensile tester, Linkam Modular Force Stage (0.1 μm, 1×10−4N resolution). The DIC speckle was applied using an airbrush technique on top of white spray paint. First, FIG. 6F shows the displacement field data measured by DIC. The DIC was done with a subset size of 23 and step size of 3 using software XX. Then, FIG. 6G shows the inversion for one of the samples. The eyeball norm suggested that the study was successfully finding the stiff particles, in addition to the printed tabs. The next steps would be to dial in the regularization to help remove noise in the lossy material.

The study also developed a vector-total-variation algorithm to characterize the response of heterogeneous materials, specifically configured for polyjet coupons made from two polymers with nearly opposite behaviors. FIG. 6H shows the behaviors of the two polymers (e.g., white/gray lossy polymer, red stiff polymer) under tensile experiment. As shown, the lossy white/gray material exhibited hyperelastic properties (i.e., underwent large displacements with low forces), while the red stiff material behaved in a linear manner, characterized by low displacement and high forces.

Initially, the vector-TV algorithm was developed to invert only for the elastic modulus field, with the Poisson ratio fixed at 0.35. However, in practice, the two polymers (stiff and lossy) exhibited different Poisson ratios. To address this, the algorithm was enhanced to invert for both the elastic modulus and Poisson ratio fields using a vectorized version of total variation, which helped align the parameter fields.

There can be two components of the data misfit term: the force and displacement contributions. The displacement component had a scaling term (out from a noise variance term) that was increasing the displacement component by 1,000, which indicated that there may be weighting applied to balance the two components. The study removed the noise variance term and instead multiplied the force contribution by a scalar, which reduced this term's influence. After that, the search directions were more stable. Previously, the search directions would search in a non-nonsensical domain and then backstep a bunch of iterations, but this behavior was stopped by weighting the force contribution. Additionally, the shadowing around the stiff particles in FIG. 6G was removed with the addition of the weighting term, which may be caused by the two reasons: (i) the term was composed of the resultant forces arising from applying DIC data at the boundaries, and DIC data can often be noisiest at the edges of the data and/or (ii) the force terms were scalars and the study a was attempting to use their gradients to inform high-dimensional fields.

The vector-total-variation (vTV) algorithm's regularization can be defined per Equation 47.

$$vTV = α \sqrt{{‖ ∇ {m}_{0} ‖}_{2}^{2} + {‖ ∇ {m}_{1} ‖}_{2}^{2} + ϵ} \qquad ( Eq . 47 )$$

Equation 47 includes a weighting term a out front. If the inversion terms, m₀ & m₁, scaled differently, then one may dominate the other. To account for this, the relationship between the inversion terms and the material model parameters can be redefined per Equation 48.

$$E = \frac{{E}_{max}}{1 + {e}^{- {m}_{0}}} , v = \frac{{v}_{max}}{1 + {e}^{- {m}_{1}}} \qquad ( Eq . 48 )$$

Equation 48 can scale E and v to realistic spaces (˜0→Eₘₐₓ, vₘₐₓ) while keeping the inversion parameters in similar magnitudes. After using vector-TV, the study inverted both parameters (with accuracy to the measured bulk properties, E_{stiff}˜366.81 N/mm), as shown in FIG. 6I.

### DISCUSSION

Inverse problems, where the input parameters are inferred from noisy observations of the data, are inherently ill-posed. This means that there may be no solution, the solution may not be unique, or it may depend sensitively on the data [6]. Slight perturbations in the data may lead to large changes in the inferred parameters. Moreover, the mapping between the parameters and observational data, the parameter-to-observable (PTO) map, is often smoothing, leading to a reduction in information. The observational data is typically corrupted by noise, such as measurement, model, or numerical. Ghattas and Wilcox lay out a methodology for handling ill-posed inverse problems in the context of partial differential equations (PDEs) [7].

They advocate for framing the inverse problem as a least-squares formulation, where the inferred parameter is regularized. The regularization term that is chosen is dependent on the problem at hand and the desired properties of the inferred parameter such as smoothness, sparsity, or sharpness [8]. Regularization works by imposing a penalty on the solution by controlling the eigenvalue modes that can cause the inference to be unstable. This improves the ill-posedness of the inverse problem. Often, solving the inverse problem is done by optimizing the least-squares formulation for the input parameter that best satisfies the data. The context of the inverse problem in this paper is mapping from images to material properties, namely ∞-dim IDIC, where noise may arise from the images, the boundary conditions, or the model itself.

The instant model may be a PDE mapping of the material parameters to the displacement field. The cost function, the least squares formulation, is the difference between an initial image and an image that is pulled back by a displacement field or between displacement fields, which is explicitly dependent on the parameter through constitutive laws [4], [9]. Notably, PDES, consisting of phase-field fracture modeling [5], elasto-plasticity [10]-[12], anisotropic linear elasticity [13], and many more, have been demonstrated. While studies attempt to use a closed form of the PDE [14]-[16], the majority use a finite element approximation. A closed form can only be found for very simple PDEs. Moreover, existing work handles the inversion in low dimensions, often a handful of parameters. In this setting, it is likely that the problem's ill-posedness is not as severe as in high-dimensional parameter spaces. Still, most authors chose to use Tikhonov regularization, such as in Neggers et al. [11], or none at all. Notably, Rokos et al. attempt to overcome the limitation of low-dimensional parameter estimation in the context of fiber-reinforced microstructures by first using ∞-dim IDIC to infer a homogenized modulus and then relying on the principle of virtual work to subsequently infer heterogeneous behavior [17]. Frankly, studies like these highlight the need for a more direct approach to inferring heterogeneity by handling ∞-dim IDIC in high-dimensional function spaces.

Unlike ∞-dim IDIC, which directly solves the inverse problem for material parameters, an alternative approach involves using image registration DIC software to acquire a displacement field, subsequently treating it as observational data. Initially devised by Kavanagh and Clough to validate Finite Element Model (FEM) predictions against DIC observations [18], this technique, known as Finite Element Model Updating (FEMU), has evolved into the most commonly used method for material parameter inference [19-22]. In particular, Elouneg et al. used FEMU to infer hyperelastic scalar parameters models similar to the PDE used in this study, although the study further inferred the spatially varying behavior [23]. A comprehensive review paper on FEMU is available [24]. Mathieu et al. found similarities between FEMU and IDIC in inferring elastoplastic parameters [10].

However, Ruybalid et al. discovered that IDIC outperforms FEMU in challenging inverse problems, such as those involving image noise, complex loading conditions, specimen misalignment, or experimental errors [25]. While FEMU is robust when the DIC algorithm accurately captures the displacement field, any error in DIC image registration can compromise the material inversion [26]. Conversely, ∞-dim IDIC (and ∞-dim DIC-based) can handle errors from both the image registration and material inversion simultaneously. Furthermore, existing works primarily focus on inferring scalar, homogeneous material parameters, neglecting spatially varying fields. This limitation underscores the need for advancement, a challenge addressed in the instant study.

NASA has initially investigated using DIC during a rocket launch (as well as helicopter and plane crashes). The public report on these studies mentions throwing out data because the current commercial codes could not handle the dimensional scale, which may be addressed using the exemplary ∞-dim IDIC or ∞-dim DIC based operation.

The exemplary approach may inspire inverse problems in other fields which are governed by PDEs. Various experimental communities could benefit from constraining an image registration problem to a PDE, such as in fluids (Particle Tracking Velocimetry) [27-32], rheometry (MicroRheometry) [33], medical (Image Registration) [34-39], robotics (Point-Set Registration) [40-44], and even more broadly for Optical Flow [45-47].

Additional Discussion. Beam bending experiments are convenient due to the ease of setup and the ability to engineer a shift from a shear to tensile-dominated failure mechanisms via expanding the span length. The instant study was conducted to identify the spatially varying material properties of a laminate structure using beam bending experiments. Kirchhoff et al. investigated a joint inversion framework for the displacement state (image registration, DIC) with the infinite-dimensional inverse problem for material properties [53]. The study aims to solve for heterogeneous material properties in a manner that is easier for practitioners to implement. The simplified framework inputs approximate displacement field data that is first computed using a commercial DIC code. The study used the displacement field data to impose Dirichlet boundary conditions and minimize the mismatch between the resultant force on the top boundary and the force measured from a load cell, which can be straightforward to implement for researchers and scientists. The study evaluated the exemplary system and method using synthetic data.

### CONCLUSION

Throughout the description and claims of this specification, the word “comprise” and other forms of the word, such as “comprising” and “comprises,” means including but not limited to, and are not intended to exclude, for example, other additives, segments, integers, or steps. Furthermore, it is to be understood that the terms comprise, comprising, and comprises as they relate to various aspects, elements, and features of the disclosed invention also include the more limited aspects of “consisting essentially of” and “consisting of.”

As used herein, the singular forms “a,” “an,” and “the” include plural referents unless the context clearly dictates otherwise. Thus, for example, reference to a “polymer” includes aspects having two or more such polymers unless the context clearly indicates otherwise.

Ranges can be expressed herein as from “about” one particular value and/or to “about” another particular value. When such a range is expressed, another aspect includes from the one particular value and/or to the other particular value. Similarly, when values are expressed as approximations, by use of the antecedent “about,” it will be understood that the particular value forms another aspect. It should be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

For the terms “for example” and “such as,” and grammatical equivalences thereof, the phrase “and without limitation” is understood to follow unless explicitly stated otherwise.

The following patents, applications and publications as listed below and throughout this document are hereby incorporated by reference in their entirety herein.

### REFERENCE LIST

[1] F. Pierron, Material Testing 2.0: A brief review, 2023.
[2] F. Pierron, M. Grediac, Towards Material Testing 2.0. A review of test design for identification of constitutive parameters from full-field measurements, Strain 57 (2021).
[3] J. Blaber, B. Adair, A. Antoniou, Ncorr: Open-Source 2D Digital Image Correlation Matlab Software, Experimental Mechanics 55 (2015) 1105-1122.
[4] G. Besnard, F. Hild, S. Roux, “Finite-element” displacement fields analysis from digital images: Application to Portevin-Le Chatelier bands, Experimental Mechanics 46 (2006) 789-803.
[5] V. Kosin, A. Fau, C. Jailin, F. Hild, T. Wick, Parameter identification of a phase-field fracture model using integrated digital image correlation, Computer Methods in Applied Mechanics and Engineering 420 (2024).
[6] A. M. Stuart, Inverse problems: A bayesian perspective, 2010.
[7] O. Ghattas, K. Willcox, Learning physics-based models from data: perspectives from inverse problems and model reduction, 2021.
[8] A. Tarantola, Inverse problem theory and methods for model parameter estimation, Society for Industrial and Applied Mathematics, 2005.
[9] S. Roux, F. Hild, Optimal procedure for the identification of constitutive parameters from experimentally measured displacement fields, International Journal of Solids and Structures 184 (2020) 14-23.
[10] F. Mathieu, H. Leclerc, F. Hild, S. Roux, Estimation of Elastoplastic Parameters via Weighted FEMU and Integrated-DIC, Experimental Mechanics 55 (2015) 105-119.
[11] J. Neggers, F. Mathieu, F. Hild, S. Roux, Simultaneous full-field multi-experiment identification, Mechanics of Materials 133 (2019) 71-84.
[12] Y. Li, J. Zhao, J. Zhou, Y. Yang, X. Huang, Z. Liu, Local-Micro-Zone-Wise Time-Resolved Integrated Digital Image Correlation for Evaluating the Mechanical Properties of Welding Joints, Experimental Techniques (2022).
[13] S. B. Lindstr\ddot{ }om, H. Wemming, Z. Kapid ̌zi\acute{ }c, M. S. Loukil, M. Segers\ddot{ }all, Integrated digital image correlation for mechanical characterization of carbon fiber-reinforced polymer plates, Composite Structures 305 (2023).
[14] S. Roux, F. Hild, Stress intensity factor measurements from digital image correlation: Post-processing and integrated approaches, volume 140, pp. 141-157.
[15] E. H\acute{ }eripr\acute{ }e, M. Dexet, J. Cr\acute{ }epin, L. G\acute{ }el\acute{ }ebart, A. Roos, M. Bornert, D. Caldemaison, Coupling between experimental measurements and polycrystal finite element calculations for micromechanical study of metallic materials, International Journal of Plasticity 23 (2007) 1512-1539.
[16] F. Mathieu, F. Hild, S. Roux, Identification of a crack propagation law by digital image correlation, International Journal of Fatigue 36 (2012) 146-154.
[17] O. Roko ̌s, R. H. Peerlings, J. P. Hoefnagels, M. G. Geers, Integrated digital image correlation for micro-mechanical parameter identification in multiscale experiments, International Journal of Solids and Structures 267 (2023).
[18] K. T. Kavanaght, W. Clough, FINITE ELEMENT APPLICATIONS IN THE CHARACTERIZATION OF ELASTIC SOLIDSt, Technical Report, 1971.
[19] Y. Sun, J. H. L Pang, C. Khuen Wong, F. Su, Finite element formulation for a digital image correlation method, Technical Report, 2005.
[20] H. Waisman, E. Chatzi, A. W. Smyth, Detection and quantification of flaws in structures by the extended finite element method and genetic algorithms, International Journal for Numerical Methods in Engineering 82 (2010) 303-328.
[21] S. S. Fayad, E. M. Jones, D. T. Seidl, P. L. Reu, J. Lambros, On the Importance of Direct-Levelling for Constitutive Material Model Calibration using Digital Image Correlation and Finite Element Model Updating, Experimental Mechanics 63 (2023) 467-484.
[22] P. Lenny, A. S. Caro-Bretelle, E. Pagnacco, Identification from measurements of mechanical fields by finite element model updating strategies: A review, European Journal of Computational Mechanics 18 (2009) 353-376.
[23] A. Elouneg, D. Sutula, J. Chambert, A. Lejeune, S. P. Bordas, E. Jacquet, An open-source fenics-based framework for hyperelastic parameter estimation from noisy full-field data: Application to heterogeneous soft tissues, Computers and Structures 255 (2021).
[24] S. Ereiz, I. Duvnjak, J. Fernando Jim\acute{ }enez-Alonso, Review of finite element model updating methods for structural applications, 2022.
[25] A. P. Ruybalid, J. P. Hoefnagels, O. van der Sluis, M. G. Geers, Comparison of the identification performance of conventional FEM updating and integrated DIC, International Journal for Numerical Methods in Engineering 106 (2016) 298-320.
[26] R. B. Lehoucq, P. L. Reu, D. Z. Turner, The Effect of the Ill-posed Problem on Quantitative Error Assessment in Digital Image Correlation, Experimental Mechanics 61 (2021) 609-621.
[27] H. G. Maas, A. Gruen, D. Papantoniou, Particle tracking velocimetry in three-dimensional flows Part 1. Photogrammetric determination of particle coordinates, Technical Report, 1993.
[28] N. A. Malik, T. Dracos, D. A. Papantoniou, Particle tracking velocimetry in three-dimensional flows Part II: Particle tracking, Technical Report, 1993.
[29] M. R. Abdulwahab¹, Y. H. Ali, F. J. Habeeb, A. A. Borhana, A. M. Abdelrhman, S. M. A. Al-Obaidi, A Review in Particle Image Velocimetry Techniques (Developments and Applications), Journal of Advanced Research in Fluid Mechanics and Thermal Sciences Journal homepage 65 (2020) 213-229.
[30] W. Brevis, Y. Ni\tilde{ }no, G. H. Jirka, Integrating cross-correlation and relaxation algorithms for particle tracking velocimetry, Experiments in Fluids 50 (2011) 135-147.
[31] Y. G. Guezennec, R. S. Brodkey, N. Trigui, J. C. Kent, Algorithms for fully automated three-dimensional particle tracking velocimetry, Technical Report, 1994.
[32] A. Schr\ddot{ }oder, D. Schanz, Annual Review of Fluid Mechanics 3D Lagrangian Particle Tracking in Fluid Mechanics, Annu. Rev. Fluid Mech. 2023 55 (2022) 511-540.
[33] A. Ahmadzadegan, H. Mitra, P. P. Vlachos, A. M. Ardekani, Particle Image micro-Rheology (PIR) using displacement probability density function, Journal of Rheology 67 (2023) 823.
[34] M. V. Wyawahare, P. M. Patil, H. K. Abhyankar, Image Registration Techniques: An overview, Technical Report 3, 2009.
[35] D. L. G Hill, P. G. Batchelor, M. Holden, D. J. Hawkes, Physics in Medicine & Biology Medical image registration Medical image registration, Technical Report, 2001.
[36] F. P. Oliveira, J. M. R. Tavares, Medical image registration: A review, Computer Methods in Biomechanics and Biomedical Engineering 17 (2014) 73-93.
[37] Y. Fu, Y. Lei, T. Wang, W. J. Curran, T. Liu, X. Yang, Deep learning in medical image registration: A review, 2020.
[38] A. Sotiras, C. Davatzikos, N. Paragios, Deformable medical image registration: A survey, IEEE Transactions on Medical Imaging 32 (2013) 1153-1190.
[39] B. Rigaud, A. Simon, J. Castelli, C. Lafond, O. Acosta, P. Haigron, G. Cazoulat, R. de Crevoisier, Deformable image registration for radiation therapy: principle, methods, applications and evaluation, 2019.
[40] R. Sandhu, S. Dambreville, A. Tannenbaum, Point set registration via particle filtering and stochastic dynamics, IEEE Transactions on Pattern Analysis and Machine Intelligence 32 (2010) 1459-1473.
[41] J. Ma, J. Zhao, A. L. Yuille, Non-rigid point set registration by preserving global and local structures, IEEE Transactions on Image Processing 25 (2016) 53-64.
[42] X. Yuan, A. Maharjan, Non-rigid point set registration: recent trends and challenges, Artificial Intelligence Review 56 (2023) 4859-4891.
[43] B. Maiseli, Y. Gu, H. Gao, Recent developments and trends in point set registration methods, 2017. [44] Z. Min, A. Zhang, Z. Zhang, J. Wang, S. Song, H. Ren, M. Q. Meng, 3-D Rigid Point Set Registration for Computer-Assisted Orthopedic Surgery (CAOS): A Review From the Algorithmic Perspective, IEEE Transactions on Medical Robotics and Bionics 5 (2023) 156-169.
[45] T. Liu, A. Merat, M. H. Makhmalbaf, C. Fajardo, P. Merati, Comparison between optical flow and cross-correlation methods for extraction of velocity fields from particle images, Experiments in Fluids 56 (2015).
[46] B. Wang, Z. Cai, L. Shen, T. Liu, An analysis of physics-based optical flow, Journal of Computational and Applied Mathematics 276 (2015) 62-80.
[47] S. T. H. Shah, X. Xuezhi, Traditional and modern strategies for optical flow: an investigation, 2021.
[48] T. F. Chan, P. Mulet, On the convergence of the lagged diffusivity fixed point method in total variation image restoration, SIAM Journal on Numerical Analysis 36 (1999) 354-367.
[49] T. F. Chan, G. H. Golub, S. J. C. Sci, A nonlinear primal-dual method for total variation-based image restoration*, SIAM J. SCI. COMPUT 20 (1999) 1964-1977.
[50] U. Villa, N. Petra, O. Ghattas, Hippylib: An extensible software framework for large-scale inverse problems governed by pdes: Part i: Deterministic inversion and linearized bayesian inference, ACM Transactions on Mathematical Software 47 (2021).
[51] J. Blaber, B. Adair, A. Antoniou, Ncorr: Open-Source 2D Digital Image Correlation Matlab Software.
[52] R. Gras, H. Leclerc, F. Hild, S. Roux, J. Schneider, Identification of a set of macroscopic elastic parameters in a 3D woven composite: Uncertainty analysis and regularization, International Journal of Solids and Structures 55 (2015) 2-16.
[53] J. Kirchhoff, D. Luo, T. O'Leary-Roseberry, O. Ghattas, Inference of heterogeneous material properties via infinite-dimensional integrated dic, 2024.
[54] M. S. Alnaes, J. Blechta, J. Hake, A. Johansson, B. Kehlet, A. Logg, C. Richardson, J. Ring, M. E. Rognes, G. N. Wells, The fenics project version 1.5.
[55] Haghighat, Ehsan, et al. “A physics-informed deep learning framework for inversion and surrogate modeling in solid mechanics.” Computer Methods in Applied Mechanics and Engineering 379 (2021): 113741.

What is claimed is:

1. A method comprising:
receiving input data comprising (i) at least two images (2D or 3D) of a feature pattern formed over a sample, including a first measured image and a second measured image, and (ii) a measurement or estimation of an induced displacement of the sample, wherein the first measured image was acquired at a first state of the sample, and wherein the second measured image was acquired at a second state different from the first state due to the induced displacement of the sample when at least one of the image was captured;
performing an inverse problem analysis configured to determine a material field data comprising a plurality of spatially varying mechanical or material parameters in a spatially varying field of the sample using (i) the at least two images or a displacement map derived from the same and (ii) the measurement or estimation of the induced displacement of the sample, wherein the determined material field data is provided as input to a physics-based model to generate a model-derived displacement estimate from the material field data, wherein the plurality of spatially varying mechanical parameters are determined for a plurality of spatially defined locations in the sample; and
outputting, via a graphical user interface or report, the plurality of spatially varying mechanical or material parameters in the spatially-varying field of the sample or a defect estimation derived therefrom, wherein the spatially varying mechanical or material parameter in the spatially-varying field of the sample or the defect estimation derived therefrom is subsequently employed in material characterization, defect estimation, and/or mechanical testing and evaluation of the sample.

2. The method of claim 1, wherein the inverse problem analysis further comprises, prior to determining the material field data, determining, via DIC analysis, a displacement field data between the first measured image and the second measured image, wherein the displacement field data is used as an input to inverse problem analysis, and wherein the inverse problem analysis is configured to determine the material field data based on predicted displacement field.

3. The method of claim 1, wherein the inverse problem analysis comprises:
a Newtonian-based operator configured to assess the displacement field data in an infinite-dimensional spatial field.

4. The method of claim 1, wherein the inverse problem analysis comprises:
a gradient-based operator configured to assess the displacement field data in an infinite-dimensional spatial field (e.g., as state variables that are regularized via a regularization model using first and second derivatives of a gradient of the at least two images and the induced displacement of the sample).

5. The method of claim 1, wherein the inverse problem analysis is configured to compute adjoint-based gradients and/or Hessian actions in a minimization operation.

6. The method of claim 5, where at least one of the adjoint-based gradients and/or Hessian actions is employed to infer a probability distribution of the plurality of spatially varying mechanical or material parameters.

7. The method of claim 1, wherein the physics-based model comprises a finite element analysis configured to generate a model-derived displacement estimate from the material field data.

8. The method of claim 1, wherein the physics-based model comprises a trained AI model, as a surrogate of a finite element analysis, configured to generate a model-derived displacement estimate from the material field data, wherein the physics-based model is selected from the group consisting of a convolutional neural network (CNN), a transformer, a Fourier neural operator, a reduced basis neural operator, or a combination thereof.

9. The method of claim 1, wherein the plurality of spatially varying mechanical or material parameters comprises at least one of a stress field, Lame parameters, modulus field, strain field, linear elasticity values, hyperelasticity values, fracture mechanic values, plasticity values, or a combination thereof, for the plurality of spatial-defined locations in the sample.

10. The method of claim 1, wherein the inverse problem analysis comprises a Newtonian-based operator or a gradient-based operator, either comprising a regularization model comprising an L²(Ω) Tikhonov regularization, an H¹(Ω) Tikhonov smoothing regularization, or primal-dual Total Variation regularization.

11. The method of claim 1, wherein the at least two measured images comprise CCD camera images, infrared camera images, sensor images, profilometer scan, microscopy images, x-ray images, or CT scan.

12. A system comprising:
a processor; and
a memory having instructions stored thereon, wherein execution of the instructions by the processor causes the processor to:
receive input data comprising (i) at least two images (2D or 3D) of a feature pattern (e.g., speckled pattern) formed over a sample, including a first measured image and a second measured image, and (ii) a measurement or estimation of an induced displacement of the sample, wherein the first measured image was acquired at a first state of the sample, and wherein the second measured image was acquired at a second state different from the first state due to the induced displacement of the sample when at least one of the image was captured;
perform an inverse problem analysis configured to determine a material field data comprising a plurality of spatially varying mechanical or material parameters in a spatially varying field of the sample using (i) the at least two images or a displacement map derived from the same and (ii) the measurement or estimation of the induced displacement of the sample, wherein the determined material field data is provided as input to a physics-based model (e.g., finite element analysis or a surrogate model trained to do the same) to generate a model-derived displacement estimate from the material field data, wherein the plurality of spatially varying mechanical parameters are determined for a plurality of spatially defined locations in the sample; and
output, via a graphical user interface or report, the plurality of spatially varying mechanical or material parameters in the spatially-varying field of the sample or a defect estimation derived therefrom, wherein the spatially varying mechanical or material parameter in the spatially-varying field of the sample or the defect estimation derived therefrom is subsequently employed in material characterization, defect estimation, and/or mechanical testing and evaluation of the sample.

13. The system of claim 13, wherein the inverse problem analysis further comprises, prior to determining the material field data, determining, via DIC analysis, a displacement field data between the first measured image and the second measured image, wherein the displacement field data is used as an input to inverse problem analysis, and wherein the inverse problem analysis is configured to determine the material field data based on predicted displacement field.

14. The system of claim 1, wherein the inverse problem analysis comprises a Newtonian-based operator configured to assess the displacement field data in an infinite-dimensional spatial field.

15. The system of claim 12, wherein the inverse problem analysis comprises a gradient-based operator configured to assess the displacement field data in an infinite-dimensional spatial field.

16. The system of claim 12, wherein the inverse problem analysis is configured to compute adjoint-based gradients and/or Hessian actions in a minimization operation.

17. The system of claim 12, wherein the physics-based model comprises a finite element analysis configured to generate a model-derived displacement estimate from the material field data.

18. The system of claim 12, wherein the physics-based model comprises a trained AI model, as a surrogate of a finite element analysis, configured to generate a model-derived displacement estimate from the material field data, wherein the physics-based model is selected from the group consisting of a convolutional neural network, a transformer, a Fourier neural operator, a reduced basis neural operator, or a combination thereof.

19. The system of claim 12 comprising:
a CCD camera, an infrared camera, a sensor, a profilometer, a microscope, an x-ray scanner, or CT scanner configured to acquire the input data for the inverse problem analysis.

20. A non-transitory computer-readable medium having instructions stored thereon, wherein execution of the instructions by a processor causes the processor to:
receive input data comprising (i) at least two images (2D or 3D) of a feature pattern formed over a sample, including a first measured image and a second measured image, and (ii) a measurement or estimation of an induced displacement of the sample, wherein the first measured image was acquired at a first state of the sample, and wherein the second measured image was acquired at a second state different from the first state due to the induced displacement of the sample when at least one of the image was captured;
perform an inverse problem analysis configured to determine a material field data comprising a plurality of spatially varying mechanical or material parameters in a spatially varying field of the sample using (i) the at least two images or a displacement map derived from the same and (ii) the measurement or estimation of the induced displacement of the sample, wherein the determined material field data is provided as input to a physics-based model to generate a model-derived displacement estimate from the material field data, wherein the plurality of spatially varying mechanical parameters are determined for a plurality of spatially defined locations in the sample; and
output, via a graphical user interface or report, the plurality of spatially varying mechanical or material parameters in the spatially-varying field of the sample or a defect estimation derived therefrom, wherein the spatially varying mechanical or material parameter in the spatially-varying field of the sample or the defect estimation derived therefrom is subsequently employed in material characterization, defect estimation, and/or mechanical testing and evaluation of the sample.
